(19) United States
(12) Patent Application Publication
(10) Pub. No.: US 2017/0233587 A1
(43) Pub. Date: Aug. 17, 2017

(54) FIRE RETARDING SYSTEM AND PROTECTIVE LAYERS OR COATINGS

(71) Applicant: Zinniatek Limited, Auckland (NZ)

(72) Inventors: John Wason McKee, Auckland (NZ); James Robert Winton, Auckland (NZ)

(73) Assignee: Zinniatek Limited, Auckland (NZ)

(21) Appl. No.: 15/504,483

(22) PCT Filed: Aug. 31, 2015
(86) PCT No.: PCT/IB2015/056583

§ 371 Date: Feb. 16, 2017

(30) Foreign Application Priority Data
Aug. 29, 2014 (NZ) 629679
Dec. 2, 2014 (NZ) 702524

(51) Int. Cl. C09D 5/18; C09K 21/14; H01L 31/0216; C09D 175/04

(52) U.S. Cl. CPC C09D 5/18; C09D 175/04; C09K 21/14; H01L 31/02167; C08K 3/2279

(57) ABSTRACT

Disclosed is a multilayer coating for a substrate such as a photovoltaic module or cell having flame retardant capability, the coating comprising two or more carrier or polymer layers, wherein at least one layer of the two or more carrier or polymer layers is a layer comprising a halogenated material and at least one other layer of the two or more carrier or polymer layers comprises at least one synergist. Also disclosed are substrates coated with the coating, a method of coating a substrate, and a method of manufacturing the coating.

### FIELD OF THE INVENTION

The invention relates to a fire retarding system, more particularly, though not limited to, laminate arrangements or coatings which incorporate a minimum of a first top sheet or layer and one or more additional or second bonding layers, the combination of such layers providing for fire or flame retarding properties or capabilities, and each layer optionally being provided with high optical transparency.

### BACKGROUND TO THE INVENTION

Laminates are useful for various applications such as, architectural panels, building materials, structural building membranes, inflatable structures, signage, window overlays, and protective films for electronic displays, photovoltaic modules, rigid composite structures and medical devices.

It is advantageous in many of these applications that the laminate exhibit flame retardant properties. There are many techniques known to those skilled in the art to impart flame retardancy to polymeric materials which are otherwise inherently combustible. In some applications, such as for photovoltaic modules, it is also desirable for the laminate to exhibit high optical transparency.

In some applications glass can be incorporated into the laminates or laminate arrangements or structures as an incombustible highly transparent top layer. The glass acts as an impermeable physical barrier to the path of the flame, but makes the laminates rigid, heavy, and prone to fouling and mechanical damage. Alternatively, transparent polymeric top sheets, which can be light weight, flexible, self-cleaning and tough when compared to glass panels, can be used instead.

Such polymeric films generally require durability in external environments where they are exposed to weathering.

Films produced from halogenated polymers are often useful as top or front layers. They can be bonded to the substrate via optionally transparent bonding layers which can be thermoplastic, thermosetting, radiation cured or pressure sensitive in nature. However, these laminates, and in particular the bonding layer, are often combustible and inherently difficult to flame retard when, for example, transparency is required to be maintained.

Flame retardants such as organic halogenated, organic non-halogenated, inorganic flame retardants, physical diluents and other additives are used to flame retard polymers. These flame retardants can work individually and synergistically by inert gas dilution, thermal quenching, protective coatings, physical dilution and chemical interaction. An overview of the art is described in Kirk-Othmer Encyclopedia of Chemical Technology 4^{th} edition.

Halogenated materials are useful as flame retardants and are generally accepted to function via a mechanism of chemical interaction. Inorganic synergists can be added to the halogenated materials in order to improve the performance of the flame retardant. However, the weathering stability of the halogenated materials can be poor and UV absorbers and stabilisers are often required to prevent discolouration. Incorporation of these flame retardants may also reduce the optical transmission of the laminates.

It is therefore an object of the present invention to provide an laminate arrangement or coating which has fire or flame retardant capability and/or which will go at least some way towards addressing the foregoing problems or which will at least provide the public with a useful choice.

In this specification where reference has been made to patent specifications, other external documents, or other sources of information, this is generally for the purpose of providing a context for discussing the features of the invention. Unless specifically stated otherwise, reference to such external documents is not to be construed as an admission that such documents, or such sources of information, in any jurisdiction, are prior art, or form part of the common general knowledge in the art.

### SUMMARY OF THE INVENTION

In one aspect the present invention consists in a multilayer coating for a substrate having flame retardant capability, the coating comprising two or more carrier or polymer layers,

wherein at least one carrier or polymer layer of the two or more carrier or polymer layers is a carrier or polymer layer comprising a halogenated material and at least one other carrier or polymer layer of the two or more carrier or polymer layers comprises at least one synergist.

In one aspect the present invention consists in a multilayer coating for a substrate having flame retardant capability, the coating comprising two or more layers,

wherein at least one layer of the two or more layers is a carrier layer comprising a halogenated material and at least one other layer of the two or more layers comprises at least one synergist.

In some embodiments, the carrier layer comprising the at least one halogenated material and the carrier layer comprising the at least one synergist are effective to provide the at least one halogenated material and the at least one synergist on thermal degradation, burning or pyrolysis.

In another aspect the present invention consists in a multilayer coating for a substrate having flame retardant capability, the coating comprising two or more polymer layers,

wherein at least one polymer layer of the two or more polymer layers comprises at least one halogenated material and at least one other polymer layer of the two or more polymer layers comprises at least one synergist.

In another aspect the present invention consists in a multilayer coating for a substrate having flame retardant capability, the coating comprising two or more polymer layers,

wherein at least one polymer layer of the two or more polymer layers comprises at least one halogenated material and at least one other polymer layer of the two or more polymer layers comprises at least one synergist,

wherein the polymer layer comprising the at least one halogenated material is a top layer and the polymer layer comprising the at least one synergist is a layer disposed beneath the top layer, and

wherein the polymer layer comprising the at least one halogenated material has a higher melting point that the polymer layer comprising the at least one synergist.

In another aspect the present invention consists in a multilayer coating for a substrate having flame retardant and optical transmission capability, the coating comprising two or more polymer layers,

wherein at least one polymer layer of the two or more polymer layers comprises at least one halogenated material and at least one other polymer layer of the two or more polymer layers comprises at least one synergist, and

wherein the coating transmits at least about 50% of incident radiation in the wavelength range of about 400-900 nm.

In another aspect the present invention consists in a multilayer coating for a substrate having flame retardant and optical transmission capability, the coating comprising two or more polymer layers,

wherein at least one polymer layer of the two or more polymer layers comprises at least one halogenated material and at least one other polymer layer of the two or more polymer layers comprises at least one synergist, and

wherein the coating transmits at least about 50% of incident radiation in the wavelength range of about 400-700 nm.

In another aspect the present invention consists in a multilayer protective coating for a photovoltaic module or cell having flame retardant and optical transmission capability, the coating comprising two or more polymer layers,

wherein at least one polymer layer of the two or more polymer layers comprises at least one halogenated material and at least one other polymer layer of the two or more polymer layers comprises at least one synergist,

wherein the protective coating transmits at least about 50% of incident radiation in the wavelength range of about 400-900 nm, and

wherein the coating is adhered to a photo-receptive side of the photovoltaic module or cell.

In another aspect the present invention consists in a multilayer protective coating for a photovoltaic module or cell having flame retardant and optical transmission capability, the coating comprising two or more polymer layers,

wherein at least one polymer layer of the two or more polymer layers comprises at least one halogenated material and at least one other polymer layer of the two or more polymer layers comprises at least one synergist,

wherein the protective coating transmits at least about 50% of incident radiation in the wavelength range of about 400-700 nm, and

wherein the coating is adhered to a photo-receptive side of the photovoltaic module or cell.

Any of the following embodiments described herein may apply to any of the aspects herein, as appropriate.

In some embodiments the halogenated material is organic.

In some embodiments the halogenated material is a halogenated polymer.

In some embodiments the halogenated polymer comprises a fluoropolymer or a chlorofluoropolymer, or a combination thereof.

In some embodiments the fluoropolymer or chlorofluoropolymer polymer comprises ethylene tetrafluoroethylene, ethylene chlorotrifluoroethylene, polyvinylidinefluoride, polyvinylfluoride, fluorinated ethylene propylene, perfluoralkoxy, polychlorotrifluoroethylene, polyvinyl chloride, polyvinylidine chloride, tetrafluoroethylene-hexafluoropropylene-vinylidene fluoride terpolymer, fluoroethylene vinyl ether, copolymers and terpolymers of vinylidene fluoride with any of hexafluoropropylene, tetrafluoroethylene, chlorotrifluoroethylene, or any combination of any two or more thereof.

In some embodiments the halogenated material is a flame retardant brominated or chlorinated organic compound or polymer.

In some embodiments the flame retardant brominated organic compound or polymer is hexabromocyclodecane, decabromodiphenyl ethane, poly(dibromostyrene), tetrabromophthalic anhydride, tetrabromophthalate diol, tetrabromophthalate ester, tetrabromobisphenol A, 2,4,6 tribromophenol, or tribromophenyl allyl ether, or any combination of two or more thereof.

In some embodiments the synergist is inorganic.

In some embodiments the synergist comprises an inorganic metal compound.

In some embodiments the metal compound comprises a zinc, tin, molybdenum, zirconium, and antimony compound, or any combination of any two or more thereof.

In some embodiments the synergist comprises an antimony compound.

In some embodiments, the antimony compound comprises antimony in the oxidation state of +5 or +3.

In some embodiments the antimony compound is an oxide of antimony.

In some embodiments the antimony compound comprises a pentavalent or trivalent oxide of antimony.

In some embodiments the oxide of antimony comprises antimony trioxide, antimony pentoxide or sodium antimonate, or a combination of any two or more thereof.

In some embodiments, the antimony compound comprises antimony pentoxide or antimony trioxide, or a combination thereof.

In some embodiments, the pentavalent oxide of antimony comprises antimony pentoxide or an antimonate salt. In some embodiments, the antimonate salt is a metal salt, for example an alkali or alkaline metal salt or a salt of a transition metal. In certain embodiments, the antimonate salt is an alkali metal salt, for example sodium antimonate.

In some embodiments the synergist is in the form of particles.

In some embodiments the particles are substantially uniformly dispersed throughout the polymer layer.

In some embodiments the size of the particles is such that the polymer layer transmits at least about 50, 60, 70, 80, or 85% of the total incident radiation in the wavelength range of about 400-900 nm.

In some embodiments the size of the particles is such that the polymer layer transmits at least about 50, 60, 70, 80, or 85% of the total incident radiation in the wavelength range of about 400-700 nm.

In some embodiments, the particles have an average particle size from about 1 to about 5000 nm, 1 to 2000 nm, 1 to 1000 nm, 5 to 1000 nm, 1 to 500 nm, 5 to 500 nm, 1 to 300 nm, 5 to 300 nm, 10 to 300 nm, 10 to 250 nm, 15 to 150 nm, 20 to 100 nm, 25 to 75 nm, or 30-40 nm.

In some embodiments the particles have an average particle size from about 1 to about 1000 nm, 1 to 500 nm, 5 to 500 nm, 1 to 300 nm, 5 to 300 nm, 10 to 300 nm, 10 to 250 nm, 15 to 150 nm, 20 to 100 nm, 25 to 75 nm, or 30-40 nm.

In some embodiments the synergist is present in an amount effective to retard combustion of the coating on thermal degradation, burning, or pyrolysis.

In some embodiments the amount of synergist is sufficient to retard combustion of the total fuel load (available combustible material) of the coating.

In some embodiments the synergist is present in an amount from about 0.1% to about 30% by weight of the polymer layer.

In some embodiments the synergist is present in an amount from about 0.5% to about 25% by weight of the polymer layer.

In some embodiments the synergist is present in an amount from about 1% to about 10% by weight of the polymer layer.

In some embodiments the synergist is present in an amount from about 2% to about 8% by weight of the polymer layer.

In some embodiments the polymer layer comprising the halogenated material is devoid of a synergist.

In some embodiments the polymer layer comprising the halogenated material is of a thickness substantially less than the polymer layer comprising the synergist.

In some embodiments the polymer layer comprising the halogenated material is devoid of a synergist, and is of a layer thickness of about: 5 μm to 1 mm thick, 5 μm to 500 μm thick, 10 μm to 500 μm thick, 5 μm to 200 μm thick, 10 μm to 200 μm thick, 15 to 200 μm thick, 10 μm to 100 μm thick, 20 to 100 μm thick, or 25 to 75 μm thick.

In some embodiments the polymer layer comprising the synergist is devoid of a flame retardant, and is of a layer thickness of about: 5 μm to 1 mm thick, 5 μm to 750 μm thick, 10 μm to 750 μm thick, 5 μm to 500 μm thick, 10 μm to 500 μm thick, 15 to 500 μm thick, 5 μm to 250 μm thick, 10 μm to 250 μm thick, 15 μm to 250 μm thick, 20 to 250 μm thick, 5 μm to 150 μm thick, 10 μm to 150 μm thick, 15 μm to 150 μm thick, 20 to 150 μm thick, or 50 to 150 μm thick.

In some embodiments one of the polymer layers comprises a halogenated polymer as a halogenated material, is devoid of an antimony compound or oxide of antimony as a synergist, and is of a layer thickness substantially less than the layer thickness of another polymer layer comprising an antimony compound or oxide of antimony as a synergist.

In some embodiments the coating has a total thickness of less than about 2 mm, 1 mm, 750 μm, 500 μm, 400 μm, 300 μm, or 250 μm.

In some embodiments at least one polymer layer of the two or more polymer layers is a thermoplastic, thermosetting, radiation cured or pressure sensitive adhesive material.

In some embodiments the polymer layer which is to be located adjacent to or upon a substrate to be coated is provided as a thermoplastic, thermosetting, radiation cured or pressure sensitive adhesive material.

In some embodiments the coating comprises more than two polymer layers.

In some embodiments the coating comprises two or more polymer layers comprising a synergist and/or two or more polymer layers comprising a halogenated material.

In some embodiments the coating is formed by a first polymer layer and a second polymer layer, wherein:

the first polymer layer comprises the at least one halogenated material and the second polymer layer comprises the at least one synergist, or

the first polymer layer comprises the synergist and the second polymer layer comprises the at least one halogenated material.

In some embodiments the first polymer layer comprises the at least one halogenated material and the second polymer layer comprises the at least one synergist.

In some embodiments the first polymer layer is a top layer and the second polymer layer is a layer disposed beneath the top layer.

In some embodiments the second polymer layer is provided to attach the first polymer layer to a substrate to receive the coating.

In some embodiments one or more additional layers are provided intermediate of the top layer and the bottom layer.

In some embodiments one or more additional polymer layers are provided intermediate to the first polymer layer and second polymer layer to attach the first polymer layer to the second polymer layer.

In some embodiments one or more additional polymer layers are provided intermediate to the second polymer layer and a substrate to receive the coating to attach the second polymer layer to the substrate to receive the coating.

In some embodiments one or more additional polymer layers that provide a physical and/or chemical barrier to reaction between the synergist and the substrate are provided intermediate to the polymer layer comprising the synergist and a substrate to receive the coating.

In some embodiments one or more additional polymer layers that inhibit or prevent degradation of the substrate by the synergist are provided intermediate to the polymer layer comprising the synergist and a substrate to receive the coating.

In some embodiments one or more additional polymer layers that inhibit or prevent corrosion of the substrate by the synergist are provided intermediate to the polymer layer comprising the synergist and a substrate to receive the coating. In some embodiments the polymer layer comprising the synergist may be formed from two or more polymer layers of the substantially the same composition comprising the synergist.

In some embodiments the coating comprises:

a first polymer layer comprising at least one halogenated material as a top layer,

a second polymer layer comprising at least one synergist disposed beneath the first layer,

optionally, one or more additional polymer layers provided intermediate to the first polymer layer and the second polymer layer to attach the first polymer layer to the second polymer layer, and

optionally, one or more additional polymer layers provided intermediate to the second polymer layer and a substrate to receive the coating to attach the second polymer layer to the substrate,

wherein the one or more additional polymer layers provided intermediate to the second polymer layer and the substrate to receive the coating inhibit or prevent degradation, for example corrosion, of the substrate by the synergist.

In various embodiments, the polymer layer comprising the at least one synergist, such as a second polymer layer, comprises two or more discrete polymer layers comprising the at least one synergist, optionally having the same or substantially the same composition.

In some embodiments the first layer is a top layer that transmits at least about 50, 60, 70, 80, or 85% of the total incident radiation in the wavelength range of about 400-900 nm, and the second layer is a layer disposed beneath the first layer.

In some embodiments the first layer is a top layer that transmits at least about 50, 60, 70, 80, or 85% of the total incident radiation in the wavelength range of about 400-700 nm, and the second layer is a layer disposed beneath the first layer.

In some embodiments the second layer, when disposed beneath the first layer, transmits at least about 50, 60, 70, 80, or 85% of the total incident radiation in the wavelength range of about 400-900 nm.

In some embodiments the second layer, when disposed beneath the first layer, transmits at least about 50, 60, 70, 80, or 85% of the total incident radiation in the wavelength range of about 400-700 nm.

In some embodiments each of the one or more polymer layers transmits at least about 50% (for example at least about 60%, 70%, 80% or 85%) of the total incident radiation in the wavelength range of about 400-900 nm.

In some embodiments each of the one or more polymer layers transmits at least about 50% (for example at least about 60%, 70%, 80% or 85%) of the total incident radiation in the wavelength range of about 400-700 nm.

In certain embodiments each of the one or more polymer layers transmits at least about 70% of the total incident radiation in the wavelength range of about 400-900 nm.

In certain embodiments each of the one or more polymer layers transmits at least about 70% of the total incident radiation in the wavelength range of about 400-700 nm.

In certain specifically contemplated embodiments each of the one or more polymer layers transmits at least about 85% of the total incident radiation in the wavelength range of about 400-900 nm.

In certain specifically contemplated embodiments each of the one or more polymer layers transmits at least about 85% of the total incident radiation in the wavelength range of about 400-700 nm.

In some embodiments the coating (as a whole) transmits at least about 50, 60, 70, 80, or 85% of the total incident radiation in the wavelength range of about 400-900 nm.

In some embodiments the coating (as a whole) transmits at least about 50, 60, 70, 80, or 85% of the total incident radiation in the wavelength range of about 400-700 nm.

In some embodiments the polymer layer comprising the at least one halogenated material has a higher melting point than the polymer layer comprising the at least one synergist.

In some embodiments the polymer layer comprising the at least one halogenated material is at least about 20, 25, 50, 75, 100, 125, 150, 175, 200, 225, or 250° C. more than that melting point of the polymer layer comprising the at least one synergist.

In some embodiments the polymer layer comprising the at least one halogenated material has a melting point from about 100 to 600° C., 150 to 550° C., or 200 to 500° C.

In some embodiments the melting point of the polymer layer comprising the synergist is from about 0 to 400° C., 50 to 350° C., or 100 to 300° C.

In some embodiments a bottom layer of the coating provided to attach the at least one other polymer layer of the coating to the substrate has a Shore D hardness of less than about 70D, and an elongation at break of at least about 100%.

In some embodiments a bottom layer of the coating provided to attach the at least one other polymer layer of the coating to the substrate has a Shore D hardness of less than about 40D, and an elongation at break of at least about 200%.

In various embodiment, the coating has peel strength between the substrate a bottom layer provided to attach the at least one other polymer layer of 50, 60, 70, 80, 90, 100, 125, 150, 200, 250, 300, 350, 400, 450, 500, 600, 700, 800, 900, 1000, 1500, 2000 N/m, or more, and useful ranges may be selected from any two or more of the preceding values, for example from 50 to 2000, 60 to 2000, 100 to 2000, 300 to 2000, 500 to 2000, 700 to 2000, 50 to 1500, 60 to 1500, 100 to 1500, 300 to 1500, 500 to 1500, or 700 to 1500, 50 to 1000, 60 to 1000, 100 to 1000, 300 to 1000, 500 to 1000, or 700 to 1000 N/m.

In some embodiments the coating has a peel strength between the substrate and a bottom layer of the coating provided to attach the at least one other polymer layer of the coating to the substrate of at least about 300 N/m.

In some embodiments the coating has a peel strength between the substrate and a bottom layer of the coating provided to attach the at least one other polymer layer of the coating to the substrate of at least about 500 N/m.

In some embodiments the coating has a cut resistance determined according to UL1703.24 (2012 revised version) of at least about 2 lb.

In various embodiments, the coating has a heat release peak in kW/m² is at least 5, 10, 15, 20, 25, 30, or 35% less than the same coating without the at least one synergist.

In various embodiments, the coating has a total heat released in MJ/m² at least 10, 15, 20, 25, 30, 35, 40, 45, or 50% less than the same coating without the at least one synergist.

In various embodiments, the heat release peak and/or total heat released is determined according to ASTM E1354-15a using a heat flux of 35 kW/m².

In various embodiments, at least one layer of the coating comprises an adhesion promoter, for example a silane, maleic anhydride, or glycidyl methacrylate based adhesion promoter.

In various embodiments, the layer comprising the adhesion promoter is an adhesion or adhering layer provided to attach a layer disposed above the adhesion or adhering layer to a layer disposed below the adhesion or adhering layer (such as a layer provided intermediate to the first polymer layer and the second polymer layer) or to attach a layer disposed above the adhesion or adhering layer to a substrate to receive the coating (such as a bottom layer or layer provided intermediate to the second polymer layer).

In some embodiments a substrate to receive the coating is one or more of: architectural panels, building or construction materials, structural building membranes, inflatable structures, signage, window overlays, electronic displays or electronic surfaces, photovoltaic modules or cells, rigid composite structures, and medical devices.

In some embodiments a substrate to receive the coating is, or comprises, a photovoltaic module or cell.

In some embodiments the coating is adhered to a photo-receptive side or surface of a photovoltaic module or cell.

In some embodiments the coating is laminated to or upon the substrate.

In some embodiments the coating is a film, sheet, coating or laminate arrangement provided for application to a substrate.

In some embodiments the coating has a class A, B, or C flame retardance rating as determined according to UL 790-2008.

In another aspect, the present invention consists in a substrate coated with a coating of the present invention.

In another aspect, the present invention consists in a photovoltaic module or cell coated with a coating of the present invention, optionally wherein the coating is adhered to a photo-receptive side or surface of the photovoltaic module or cell.

In some embodiments the coating is adhered to a photo-receptive side or surface of the photovoltaic module or cell.

In another aspect the present invention consists in a method of coating a substrate with a coating, comprising laminating the coating of the present invention.

In some embodiments the coating encapsulates or is encapsulating of the substrate.

In yet another aspect, there is provided a method of manufacturing a coating of the present invention. The method comprises the steps of:

providing at least one polymer with at least one synergist, where the at least one synergist is substantially uniformly dispersed within the at least one polymer,

providing at least one other polymer comprising at least one halogenated material, and

joining, laying upon each other or otherwise laminating together the, or each of the, at least one polymer and the at least one other polymer as separate layers of a protecting coating or the protective coating as herein defined.

In some embodiments the at least one polymer is provided in the form of a laminate comprising a layer of the at least one polymer and one or more additional polymer layers.

In some embodiments the at least one other polymer is provided in the form of a laminate comprising a layer of the at least one other polymer and one or more additional polymer layers.

In some embodiments the method comprises:

providing a laminate comprising a layer of the at least one polymer and one or more additional polymer layers,

providing a laminate comprising a layer of the at least one other polymer and one or more additional polymer layers, and

joining, laying upon each other or otherwise laminating together the laminate comprising the at least one polymer and the laminate comprising the at least one other polymer.

In some embodiments the laminate comprising the at least one other polymer comprises a polymer layer comprising at least one synergist as a bottom layer.

In some embodiments the layer of the at least one polymer is a top layer, and the method comprises laminating the top layer of the laminate comprising the at least one polymer and the synergist containing bottom layer of the laminate comprising the at least one other polymer to provide a single polymer layer comprising at least one synergist.

In some embodiments the method comprises the steps of:

providing a first laminate comprising
a layer of the at least one polymer with at least one synergist as a top layer, and
optionally one or more additional polymer layers provided intermediate to the top layer and a substrate to receive the coating to attach the top layer to the substrate,
wherein the one or more additional polymer layers intermediate to the top layer and the substrate to receive the coating inhibit or prevent degradation of the substrate by the synergist,

providing a second laminate comprising
a layer of the at least one other polymer comprising at least one halogenated material as a top layer,
a polymer layer comprising at least one synergist as a bottom layer, and
optionally one or more additional polymer layers provided intermediate to the top layer and a bottom layer to attach the top layer to the bottom layer, and

joining, laying upon each other or otherwise laminating together the top layer of the first laminate and the bottom layer of the second laminate.

In some embodiments the composition of the top layer of the first laminate and the composition of the bottom layer of the second laminate is substantially the same.

In some embodiments laminating the top layer of the first laminate and the bottom layer of the second laminate provides a single polymer layer comprising the at least one synergist.

In various embodiments, the single polymer layer comprising the at least one synergist comprises discrete layers of the top layer of the first laminate or laminate comprising at least one polymer and the bottom layer of the second laminate or laminate comprising at least one other polymer.

In some embodiments the single polymer layer comprising at least one synergist is of a layer thickness of about 5 μm to 1 mm thick, 5 μm to 750 μm thick, 10 μm to 750 μm thick, 5 μm to 500 μm thick, 10 μm to 500 μm thick, 15 to 500 μm thick, 5 μm to 250 μm thick, 10 μm to 250 μm thick, 15 μm to 250 μm thick, 20 to 250 μm thick, 5 μm to 150 μm thick, 10 μm to 150 μm thick, 15 μm to 150 μm thick, 20 to 150 μm thick, or 50 to 150 μm thick.

In another aspect, the present invention provides a laminate, for example a first laminate or a second laminate, for use in the method of manufacturing a coating of the present invention.

In some embodiments, the coating is a form provided as a length L and of width W is wound upon a roll for a subsequent unrolling and coating or lamination to a substrate to be coated by the coating.

In some embodiments, the coating is provided with at least one release sheet, which upon release exposes a surface of the coating for coating or lamination or otherwise adhesion or connection or joining to a substrate.

The present invention relates to a flame retardant, multi-layer laminate, optionally with high optical transparency.

Preferably one layer contains a halogenated material either as a polymer or additive.

Preferably a top (or upper-most) layer contains a halogenated material either as a polymer or additive.

Preferably the halogen containing layer (or layers) comprise a fluoropolymer or chlorofluoropolymer.

Preferably at least one underlying layer or layer positioned between a top layer and a substrate to receive the laminate, is one or more of a: thermoplastic, thermosetting, radiation cured or pressure sensitive material.

Preferably at least one layer comprises an antimony compound.

Preferably the antimony compound comprises a pentavalent oxide of antimony, such as antimony pentoxide or sodium antimonate.

Preferably the antimony compound comprises antimony pentoxide.

Preferably at least one layer comprises an antimony compound comprising a pentavalent antimony compound, such as antimony pentoxide or sodium antimonate, provided as a total weight percentage of about 0.1% to about 50% of the layer, more preferably about 0.25% to about 25%, even more preferably about 5% to about 10%.

Preferably at least one layer comprises an antimony compound comprising antimony pentoxide provided as a total weight percentage of about 0.1% to about 50% of the layer, more preferably about 0.25% to about 25%, even more preferably about 5% to about 10%.

Preferably the multi-layer laminate has a high optical transparency. More preferably, wherein the optical transparency is greater than about 50%, even more preferably greater than about 60%, most preferably greater than about 70%, or 80% or 90%, or 95%.

It will be appreciated that the various polymers or layers of this invention as described herein may be provided as carrier layers or a carrier system or various sacrificial layers or materials which carry or provide the halogen or halogenated material and synergist.

Carrier materials or layers or sacrificial layers or materials may be applicable or provide particular utility here for placing or providing the halogen or halogenated material and synergist in proximity or substantially adjacent proximity with each other, such that during exposure to a fire or similarly elevated temperatures or thermal degradation or pyrolysis, the halogen or halogenated material and synergist are made more freely or readily available for their combination.

The term “comprising” as used in this specification and claims means “consisting at least in part of”. When interpreting each statement in this specification and claims that includes the term “comprising”, features other than that or those prefaced by the term may also be present. Related terms such as “comprise” and “comprises” are to be interpreted in the same manner.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

As used herein the term “and/or” means “and” or “or”, or both.

As used herein “(s)” following a noun means the plural and/or singular forms of the noun.

This invention may also be said broadly to consist in the parts, elements and features referred to or indicated in the specification of the application, individually or collectively, and any or all combinations of any two or more said parts, elements or features, and where specific integers are mentioned herein which have known equivalents in the art to which this invention relates, such known equivalents are deemed to be incorporated herein as if individually set forth.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

The invention consists in the foregoing and also envisages constructions of which the following gives examples only.

### BRIEF DESCRIPTION OF THE DRAWINGS

Preferred embodiments of the invention will be described by way of example only and with reference to the drawings, in which:

FIG. 1 illustrates one arrangement of the invention in which there is provided a top layer and an underlying layer laid upon the surface of a substrate.

FIG. 2 illustrates another embodiment of the invention in which there is provided a top layer, an intermediate layer and an underlying layer laid upon the surface of a substrate.

FIG. 3 illustrates a further generalised embodiment in which a base layer is provided laid upon the surface of a substrate, the base layer having one or more additional layers provided on top of the base layer.

FIG. 4 is an example of a generalised coating as provided, for example in FIG. 3, being wound up upon a roll for subsequent use.

FIG. 5 is illustrates a further generalised embodiment of a coating in which there is provided a top layer, a first intermediate layer, an underlying layer, and a base layer laid upon the surface of a substrate.

FIG. 6 illustrates an embodiment of a method of manufacturing a coating of the invention.

FIG. 7 shows a plot of the heat release rate (in kW/m²) over time (in seconds) for two coatings of the invention—sample 1 (solid line: [symbol] ) and sample 2 (dotted line: [symbol] )—compared to a coating that did not include a layer comprising a synergist—sample 3 (dashed line: [symbol] ).

### DETAILED DESCRIPTION OF PREFERRED EMBODIMENTS

The present invention advantageously provides for a system or coating arrangement in which a substrate may be protected or be provided with a level of flame retardancy protection. Whilst other flame protection coatings are provided in the industry, the present invention aims to provide for another alternative solution.

The following description is indicative only, and made with reference to the accompany figures. The same reference numerals are used throughout to designate the same or similar components in the various embodiments described.

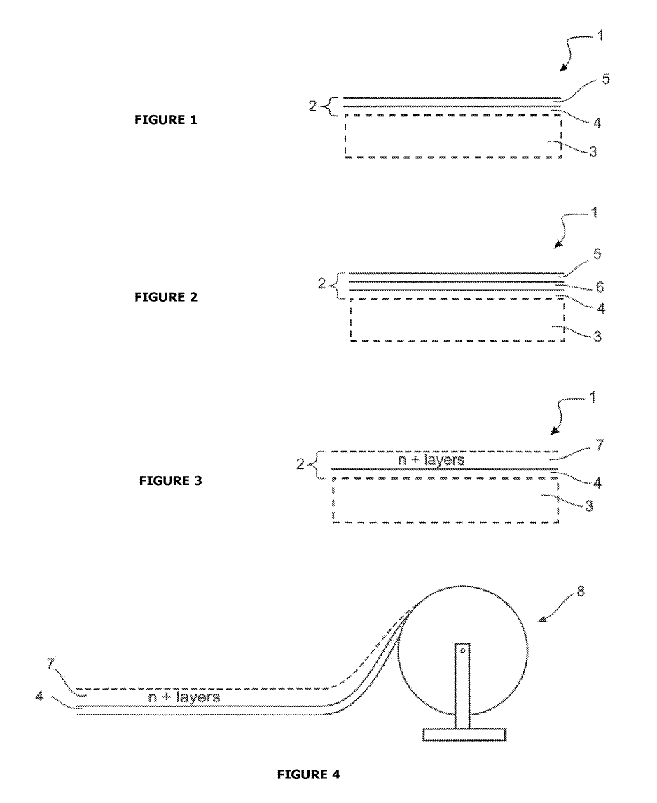

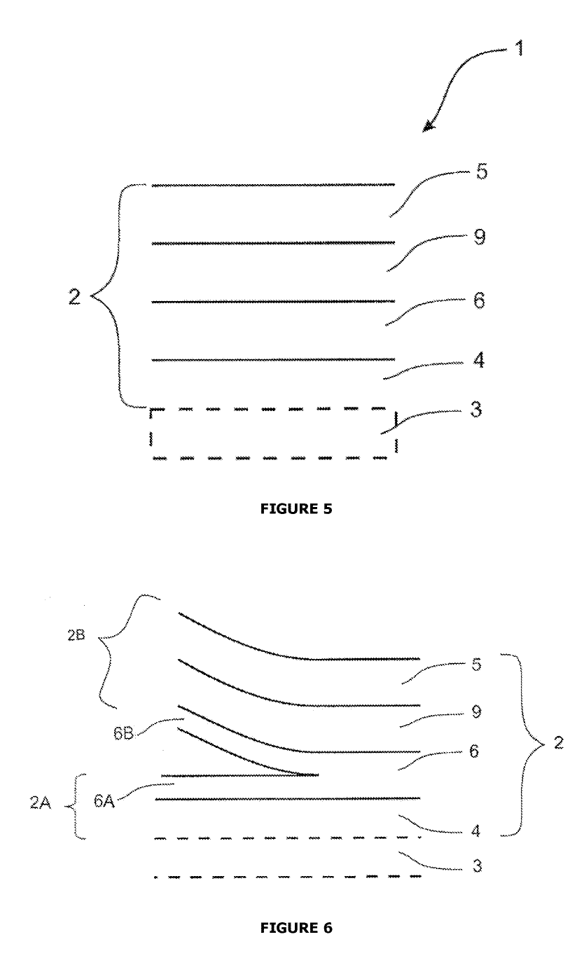

Accordingly, in one aspect, there is provided a protective coating 2 for a substrate 3 to be protected, or at least provided with a level of flame protection. In some embodiments, at the same time, the protective coating facilitates a desirable level of optical transmission so that the substrate may still receive or be exposed to the optical transmission. A coating protected substrate is shown as item 1 in each of FIGS. 1-3 and also in FIG. 5.

Advantageously, the coating 2 has flame retardant and, in some embodiments, optical transmission capabilities. The coating 2 can comprise of two or more polymer layers (such as layers 4, 5, 6, 7 shown in FIGS. 1-4).

Each of the one or more layers may be sufficiently optically transparent so as to allow transmission of light incident upon the two or more layers to a substrate 3 upon which the two or more polymer layers are laminated or are to be laminated thereupon. The two or more polymer layers comprise at least one polymer layer comprising at least one halogenated material, and at least one polymer layer comprising at least one synergist.

The halogenated material is or comprises of an organic halogenated material, for example a halogenated polymer or flame retardant brominated or chlorinated organic compounds or polymers. Examples of halogenated polymers and flame retardant brominated or chlorinated organic compounds or polymers are provided in this specification. Other halogenated polymers and flame retardant brominated or chlorinated organic compounds or polymers will be apparent to those skilled in the art.

It will be appreciated non-halogenated polymers or materials may also be used which are then provided with a halogenated polymer or halogenated material.

The synergist may, in combination with a halogenated material, produce and/or enhances flame retardance on thermal degradation, burning, or pyrolysis of the protective coating or arrangement. The synergist can be inorganic, for example an inorganic metal compound. Inorganic metal compounds include, but are not limited to, compounds of zinc, tin, molybdenum, zirconium, and antimony, for example oxides of these metals.

Examples of zinc and tin compounds include anhydrous and hydrated zinc stannate, stannic oxide, and zinc oxide.

Examples of molybdenum compounds include molybdic oxide, ammonium octamolybdate, and zinc molybdate.

In one preferred embodiment the synergist is or comprises of an antimony compound.

Where an antimony compound is utilised, the compound may be an oxide of antimony, for example antimony pentoxide, or antimony trioxide, or a combination thereof. The oxide of antimony may be a pentavalent oxide of antimony comprising antimony in the +5 oxidation state or a trivalent oxide of antimony comprising antimony in the +3 oxidation state. Examples of pentavalent oxides of antimony include but are not limited to antimony pentoxide and antimonate salts, for example, salts of metals. The metal salt may be an alkali, alkaline or transition metal salt. In one form, the antimonate salt is an alkali metal antimonate, such as sodium antimonate. Examples of trivalent oxides of antimony include but are not limited to antimony trioxide.

The synergist can be provided in the form of nanoscale particles to be homogenously or uniformly or highly dispersed into a polymeric material to subsequently form a layer of the protective coating of this invention.

The synergist can be selected so that the size of the particles is such that the polymer layer is optically transparent/transmissive, for example transmits at least about 50, 60, 70, 80, or 85% of the total incident radiation in the wavelength range of about 400-900 nm or about 400-700 nm. Large particles may reduce optical transmission.

The particles may have an average particle size from about 1 to about 1000 nm or, in some embodiments larger than 1000 nm, for example, from about 1 to about 5000 nm. Smaller particles generally may be incorporated into the polymer layer at higher levels than larger particles while maintaining comparable optical transmission. In embodiments where optical transparency is required, the average particle size may be less than about 300 nm, for example from about 1 to 300 nm, 5 to 300 nm, or 10 to 300 nm. In certain embodiments, the average particle size is from about 30 to 40 nm.

In some embodiments, the synergist and/or halogenated material are present in an amount effective to retard combustion of the coating on thermal degradation, burning, or pyrolysis.

In a particularly preferred embodiment, the synergist is present in an amount effective to retard combustion of the coating on thermal degradation, burning, or pyrolysis. More advantageously, the amount of synergist provided is sufficient to retard combustion of the total fuel load (available combustible material) of the protective coating.

For example, the synergist may be present in an amount from about 0.1% to about 30%, from about 0.5% to about 25%, from about 0.5 to about 20%, from about 1 to about 20%, from about 1 to about 15%, from about 1% to about 10%, from about 1 to about 8% by weight of the polymer layer in which it is present. In certain embodiments, the synergist is present in an amount from about 2% to about 8% by weight of the polymer layer, for example, 5% of the polymer layer.

It will be appreciated that incorporating high levels of the synergist into the polymer layer may reduce optical transmission. In embodiments where the coating has optical transmission capability, the synergist is present in an amount of less than about 15%, 12%, 11%, or 10% by weight of the polymer layer.

In some embodiments, the synergist is present in an amount of at least about 2%, 2.5%, 3%, or 3.5%.

The protective coating comprises two or more polymer layers (see for example FIGS. 1-3). At least one polymer layer of the two or more polymer layers comprises the at least one halogenated material and at least one other polymer layer of the two or more polymer layers comprises the at least one synergist. The polymer layer comprising the halogenated material may be devoid of a synergist. Similarly, the polymer layer comprising synergist may be devoid of a halogenated material.

Various arrangements and thicknesses of layers can be provided. For example, the polymer layer comprising the halogenated material may have a layer thickness substantially less than that of the polymer layer comprising the synergist.

In one form, a polymer layer comprising of a halogenated material that is devoid of a synergist is of a thickness substantially less than a polymer layer comprising of a synergist.

In more detail, for example a polymer layer comprising of a halogenated material and that is devoid of a synergist, may be of a layer thickness of: 5 μm to 1 mm thick, 5 μm to 500 μm thick, 10 μm to 500 μm thick, 5 μm to 200 μm thick, 10 μm to 200 μm thick, 15 to 200 μm thick, 10 μm to 100 μm thick, 20 to 100 μm thick, or 25 to 75 μm thick.

In another example, a polymer layer comprising of a synergist and that is devoid of a halogenated material, may be of a layer thickness of: 5 μm to 1 mm thick, 5 μm to 750 μm thick, 10 μm to 750 μm thick, 5 μm to 500 μm thick, 10 μm to 500 μm thick, 15 to 500 μm thick, 5 μm to 250 μm thick, 10 μm to 250 μm thick, 15 μm to 250 μm thick, 20 to 250 μm thick, 5 μm to 150 μm thick, 10 μm to 150 μm thick, 15 μm to 150 μm thick, 20 to 150 μm thick, or 50 to 150 μm thick.

The total thickness of the coating is in some embodiments less than about 2 mm, 1 mm, 750 μm, 500 μm, 400 μm, 300 μm, or 250 μm. Thicker coatings generally have greater total fuel load than thinner coatings, and so higher levels of halogenated material and/or synergist may be required for a thicker coating to provide a desired flame retardant capability.

As demonstrated above, where one of the polymer layers comprises a halogenated polymer as a halogenated material and is devoid of an antimony compound or oxide of antimony as a synergist, that layer thickness can be substantially greater than the layer thickness of another polymer layer comprising an antimony compound or oxide of antimony as a synergist.

At least one of the polymer layers of the protective coating, may be a thermoplastic, thermosetting, radiation cured or pressure sensitive adhesive material. It will be appreciated that a polymer layer which is to be located adjacent or upon a substrate to be protected, for example the layer indicated as 4 can be provided as a thermoplastic, thermosetting, radiation cured or pressure sensitive adhesive material.

The coating may comprise more than two polymer layers. For example, in some embodiments, the coating comprises three or more, four or more, five or more, or six or more polymer layers. In other embodiments, the coating comprises from two to ten, two to eight, two to six, two to five, or two to four polymer layers.

In embodiments, where the coating comprises more than two polymer layers, the coating may comprise two or more polymer layers comprising a synergist and/or two or more polymer layers comprising a halogenated material.

The coating can be formed by a first polymer layer and a second polymer layer, wherein:

the first polymer layer comprises the at least one halogenated material and the second polymer layer comprises the at least one synergist, or

the first polymer layer comprises the synergist and the second polymer layer comprises the at least one halogenated material.

In one form, the first polymer layer comprises the at least one halogenated material, and the second polymer layer comprises the synergist.

The first polymer layer can be a top layer (e.g. layer 5 or 7 in the figures) and the second polymer layer is a layer disposed beneath the top layer.

It will be appreciated one of the layers of the coating can be provisioned as an adhesion or adhering layer for connection of one or more additional layers to a substrate to be coated or laminated. For example, the second polymer layer can be provided to attach the first polymer layer to a substrate to receive the coating. FIGS. 1-3 illustrate an arrangement in which a top layer (items 5, 7) is situated above or on top of second or other layers (items 4, 6 or intervening layers making up the layer n+layers). In these sequences or arrangements, it will be appreciated the one or more additional layers are provided intermediate of the top layer and the bottom layer.

FIG. 4 illustrates an embodiment in which a protective coating may be manufactured, then stored in roll form for subsequent use or high-speed or high through-put manufacturing lamination operations.

In more detail, FIG. 5 for example, illustrates a coating wherein an adhesion or adhering layer (9) is provided to attach the first polymer layer (5) to the second polymer layer (6), and another polymer layer (4) is provided to attach the second polymer layer (6) to the substrate (3). The adhering layer(s) may be provided in the form of a thermoplastic, thermosetting, radiation cured or pressure adhesive material, and may additionally comprise one or more adhesion promoters, such as a silane or maleic anhydride, including maleic anhydride modified polymers, maleic anhydride grafted polymers, and other maleic anhydride based polymers.

Any suitable adhesion promoter may be used. In various embodiments, the adhesion promoter comprises a silane, maleic anhydride or glycidyl methacrylate adhesion promoter. Examples of silane and silane based adhesion promoters useful herein include but are not limited to silane cross-linking resins (polyolefins, for example low-density-polyethylene, high-density polyethylene, polypropylene, and ethylene PVC copolymer) such as those manufactured by Mitsubishi Chemical under the tradename Linklon™. Maleic anhydride adhesion promoters useful herein include but are not limited to polymers modified by maleic anhydride grafting, such as those manufactured by Dupont under the tradename Fusabond®, and other maleic anhydride based polymers. Glycidyl methacrylate adhesion promoters include, for example, ethylene/n-butyl acrylate/glycidyl methacrylate copolymers such as Elvaloy® PTW manufactured by Dupont, and other glycidyl methacrylate based adhesion promoters. Other suitable adhesion promoters will be apparent to those skilled in the art.

In some embodiments, the first polymer layer (5) comprises the at least one halogenated material and the second polymer layer (6) comprises the at least one synergist.

In some embodiments, the polymer composition of the layer comprising the at least one synergist (6) and the polymer composition of one or more of the adhesion or adhering layers (9 and 4) may be the same. Typically the adhesion or adhering layer(s) do not comprise a flame retardant compound, or synergist.

Those skilled in the art will appreciate that adhesion or adhering layer(s) contribute to the total fuel load of the coating. As such, in certain embodiments, it may be useful to minimise the number of and thickness of such layers in the coating.

Where the second layer (6) comprises at least one synergist, the polymer layer (4) provided intermediate to the second polymer layer and the substrate may also act as a physical and/or chemical barrier for preventing undesirable chemical reactions between the synergist and the substrate.

Some synergists, such as those formed from pentavalent antimony, for example antimony pentoxide, have inherent ion exchange capacity. The ion exchange capacity depends on the synergist. Sodium antimonate, for example, has a very low ion exchange capacity.

Ion exchange capacity in a synergist can lead to undesirable effects in materials which it is in direct contact with, such as corrosion or degradation, for example when exposed to moisture. Therefore, when the substrate or some component therein is susceptible to ion exchange capacity, an additional polymer layer that physically separates or provides a chemical barrier between the synergist and substrate may be useful for preserving the substrate.

The additional polymer layer may be capable of inhibiting degradation of the substrate, for example corrosion, catalytic depolymerisation, or acidification of the substrate.

Polymer layers of the coating may be formed from two or more polymer layers of substantially the same composition, for example by laminating the two or more polymer layers to provide a single polymer layer. For example, in FIG. 5, the second polymer layer (6) which may comprise the at least one synergist may be formed by joining, laying upon or otherwise laminating two or more polymer layers having substantially the same composition, as shown in FIG. 6. It will be appreciated that the polymer layers from which the single polymer layer is formed may exist in the coating as discrete layers or there may be no discontinuity in the single polymer layer between the layers from which it is formed. In certain preferred embodiments, the polymer layer comprising the at least one synergist, such as a second polymer layer, comprises two or more discrete polymer layers comprising the at least one synergist.

For example, a plurality of pre-formed layers may be pre-formed and then subsequently joined or laminated to other pre-formed layers. Such a joined or laminated arrangement of pre-formed layers may themselves be used to constitute a “layer” of the various embodiments described herein. That is, a layer may itself be formed of a plurality of pre-formed discrete layers, although there may be no or substantially no compositional difference between such pre-formed layers that are joined or laminated together for a subsequent joining or lamination operation; and in an alternative the plurality of pre-formed discrete layers may be of different composition.

It will be also be appreciated that a series of discrete layers may be joined together to form the coating of the invention herein, and each of those discrete layers may themselves be made up of two or more, or a series, of individual or so-called ‘discrete’ layers.

The coating, or one more layers thereof, may have optical transmission capability. In some embodiments, the coating is optically transparent. In other embodiments, the coating comprises one or more optically transparent polymer layers disposed above one or more opaque polymer layers.

For example, in some embodiments, the first layer is a top layer that transmits at least about 50, 60, 70, 80, or 85% of the total incident radiation in the wavelength range of about 400-900 nm or about 400-700 nm, and the second layer is a layer disposed beneath the first layer. In some embodiments, the second layer also transmits at least about 50, 60, 70, 80, or 85% of the total incident radiation in the wavelength range of about 400-900 nm or about 400-700 nm. In other embodiments, the second layer or a layer disposed beneath the second layer is opaque.

In some embodiments, each of the one or more polymer layers of the coating transmits at least about 50, 60, 70, 80, or 85% of the total incident radiation in the wavelength range of about 400-900 nm or about 400-700 nm, such that the coating has optical transmission capability.

In some embodiments, the coating transmits at least about 50, 60, 70, 80, or 85% of the total incident radiation in the wavelength range of about 400-900 nm or about 400-700 nm. Such coatings can be useful for application to substrates such as photovoltaic modules or cells.

In some embodiments, the coating or polymer layers thereof may transmit more than about 85%, for example at least about 90, 95, 97, 98, or 99%, of the total incident radiation in the wavelength range of about 400-900 nm or about 400-700 nm.

The transmission of the coating or polymer layers of the coating, as appropriate may be determined according to ASTM D1003-2013, taking average transmission in the range 400-900 nm or about 400-700 nm, as appropriate.

In some embodiments, the polymer layer comprising the at least one halogenated material has a higher melting point than the polymer layer comprising the at least one synergist.

In one embodiment, the polymer layer comprising the halogenated material is disposed above, for example a top layer, the polymer layer comprising the synergist.

In an alternate embodiment, the polymer layer comprising the halogenated material is a layer disposed below the polymer layer comprising the synergist.

The melting point of the polymer layer comprising the at least one halogenated material may be at least about 20, 25, 50, 75, 100, 125, 150, 175, 200, 225, or 250° C. more than that melting point of the polymer layer comprising the at least one synergist.

In certain embodiments, the melting point of the polymer layer comprising the at least one halogenated material may be from about 100 to 600° C., 150 to 550° C., or 200 to 500° C. For example, the melting point may be from about 300 to 600, 350 to 550, or 400 to 500° C.

In certain embodiments, the melting point of the polymer layer comprising the synergist may be from about 0 to 400° C., 50 to 350° C., or 100 to 300° C. For example, the melting point may be from about 150 to 400, 175 to 350, or 200 to 300° C.

A bottom layer of the coating provided to attach the at least one other polymer layer of the coating to the substrate may have a Shore D hardness of less than about 70D, and an elongation at break of at least about 100%. For example, the bottom layer may have a Shore D harness of less than about 65D, 60D, 55D, 50D, 45D, or 40D, and an elongation at break of at least about 125, 150, 175, or 200%. In certain specifically contemplated embodiments, the Shore D hardness is less than about 40D and the elongation at break is at least about 200%. The Shore hardness may be determined according to ASTM D2240-2005, and the elongation at break may be determined according to ASTM D882-2012.

The peel strength between the substrate and a bottom layer of the coating may be 50, 60, 70, 80, 90, 100, 125, 150, 200, 250, 300, 350, 400, 450, 500, 600, 700, 800, 900, 1000, 1500, 2000 N/m, or more. In various embodiments, the peel strength may be from 50 to 2000 N/m.

The coating may have peel strength between the substrate and a bottom layer of the coating provided to attach the at least one other polymer layer of the coating to the substrate of at least about 300 N/m. For example, the peel strength between the substrate and the bottom layer may be at least about 325, 350, 375, 400, 425, 450, 475, or 500 N/m. In certain specifically contemplated embodiments, the peel strength at least about 500 N/m. The peel strength may be determined according to ASTM D1876-08.

In certain applications, a coating having high cut resistance may be provided. In certain embodiments, the coating has a cut resistance determined according to UL1703.24 (2012 revised version) of at least about 2 lb, for example at least about 2.25, 2.5, or 2.75 lb.

Various applications or substrates to receive a coating are envisaged and which may particularly benefit from such a protective coating, include but are not necessarily limited to: architectural panels, building or construction materials, structural building membranes, inflatable structures, signage, window overlays, electronic displays or electronic surfaces (e.g. LEDs), photovoltaic modules or cells, rigid composite structures, medical devices, or aircraft or automobile interiors. Of particular importance may be a photovoltaic module or cells which are integrated as part of building structures and so which require improved flame retardancy, yet which must simultaneously achieve a minimum optical transparency so that the photovoltaic module may operate in an efficient manner.

In one form, the coating is a film, sheet, coating or laminate arrangement provided for application to a substrate. In another form, the coating is laminated to or upon the substrate.

The coatings of the present invention have flame retardant capability, preferably high flame retardant capability. There are numerous methods for determining and rating systems for classifying flame retardance.

In some embodiments, the coating has a class A, B, or C flame retardance rating as determined according to UL 790-2008. In another embodiment, the coating has a class A, B, or C flame retardance rating as determined according to ASTM E-108.

More specifically, the coating has a class A, B, or C flame retardance rating as determined by a spread of flame test performed using a flame and airspeed as specified in UL790-2008 or ASTM E-108. The test rig may be oriented at 22 degrees above horizontal.

In certain embodiments, the coating may have a class A or class B rating. In certain specifically contemplated embodiments, the coating has a class A rating.

As shown in the examples below, in certain preferred embodiments, the coatings have a substantially lower heat release peak and/or total heat release compared to the same coating without the at least one synergist being present. The heat release peak in kW/m² and total heat released in MJ/m² of a coating may be determined by for example cone calirometry, for example according to ASTM E1354-15a using a heat flux of 35 kW/m².

In another aspect, there is provided a substrate coated with a multilayer coating of the present invention.

In yet another aspect, there is provided a photovoltaic module or cell coated with a multilayer coating of the present invention. The coating may, in some embodiments, be adhered to a photo-receptive side or surface of the photovoltaic module or cell. In such embodiments, the coating has high optical transparency and transmits, for example, at least about 50, 60, 70, 80, or 85% of the total incident radiation in the wavelength range of about 400-900 nm or about 400-700 nm.

In yet another aspect, there is provided a method of coating a substrate with a coating. The method comprises laminating the coating as defined in any one of the preceding claims to a substrate. The coating may encapsulate or be encapsulating of the substrate.

The lamination may be carried out by any suitable method. For example, where a bottom layer of the coating comprises a pressure sensitive material, the coating may be laminated by applying the coating to a surface of a substrate with pressure and optionally heat so as to cause the bottom layer to adhere to the surface of the substrate.

In yet another aspect, there is provided a method of manufacturing a coating of the present invention. The method comprises the steps of:

providing at least one polymer with at least one synergist, where the at least one synergist is substantially uniformly dispersed within the at least one polymer,

providing at least one other polymer comprising at least one halogenated material, and

joining, laying upon each other or otherwise laminating together the, or each of the, at least one polymer and the at least one other polymer as separate layers of a protecting coating or the protective coating as herein defined.

The at least one polymer and at least one synergist may be formed using, for example, a high speed mixer as described in the Examples below, such as a screw or ribbon mixer.

Those skilled in the art will be able to determine appropriate conditions for dispersing the synergist in the at least one polymer. In certain embodiments, the method comprises combining the at least one polymer, the at least one synergist, and at least one dispersant.

The at least one polymer and at least one other polymer are joined, laid upon each other or otherwise laminated together such that a coating comprising the at least one polymer and at least one other polymer as separate layers is formed.

The at least one polymer and/or at least one other polymer may each be provided in the form of a single polymer layer. Alternatively, the at least one polymer and/or at least one other polymer may each be provided in the form of a laminate. The laminate comprises a layer of either the at least one polymer or at least one other polymer, as appropriate, and one or more additional polymer layers. In certain embodiments, the at least one polymer and at least one other polymer are each provided in the form of a laminate.

Where one of the at least one polymer and the at least one other polymer is provided in the form of a laminate, the coating provided by joining, laying upon each other or otherwise laminating together the at least one polymer and the at least one other polymer as separate layers may comprise one or polymer layers intermediate to the layer of the at least one polymer and the layer of the at least one other polymer.

The method may comprise joining or otherwise laminating two or more polymer layers of substantially the same composition to provide a single polymer layer of the coating. In certain embodiments the layer thickness of the single polymer layer is equivalent to the sum of the layer thicknesses the two or more polymer layers from which the single polymer layer is formed.

FIG. 6 illustrates an embodiment wherein the coating (2) is formed by joining or otherwise laminating a first laminate (2A) and second laminate (2B). The first laminate may comprise as a top layer the at least one polymer with at least one synergist (6A) and one or more additional polymer layers (4) to attach the top layer to a substrate (3) to receive the coating. The polymer layer (4), as noted above, may additionally act as a barrier to prevent reaction between the synergist and the substrate.

The second laminate may comprise as a top layer the at least one other polymer comprising at least one halogenated material (5), and one or more additional polymer layers (9, 6B). The one or more additional polymer layers may comprise a polymer layer comprising at least one synergist (6B) as a bottom layer, and an adhesion or adhering layer (9) to attach the top layer (5) to the bottom layer (6B).

The top layer (6A) of the first laminate (2A) and bottom layer (6B) of the second laminate (2B) may be joined, laid upon each other, or otherwise laminated to provide the coating (2).

In certain embodiments, the top layer (6A) of the first laminate (2A) and bottom layer (6B) of the second laminate (2B) have substantially the same composition, and joining or laminating the layers (6A and 6B) provides a single polymer layer (6) comprising the synergist of substantially the same composition.

Such a method allows the formation of a single layer having a greater thickness than either of the layers from which it is formed. In certain embodiments, the layer thickness of the single layer (6) is equivalent to the sum of the layer thicknesses of the polymer layers (6A, 6B) from which it is formed. The layer thickness of the single polymer layer comprising the at least one synergist may, as described herein, range from about 5 μm to 1 mm thick.

Forming a single polymer layer comprising the at least one synergist from two or more thinner polymer layers may be advantageous where it is easier to extrude to two or more thinner polymer layers or where it is difficult to provide a single thicker layer, for example by extrusion, in the first instance or there are disadvantages in doing so.

Forming a single polymer layer comprising the at least one synergist from two or more thinner polymer layers having substantially the same composition may also allow the synergist to be more evenly distributed throughout the single polymer layer.

It will be apparent that in certain embodiments, joining or laminating the top layer (6A) of a first laminate (2A) and the bottom layer (6B) of a second laminate (2B) of the same or substantially the same composition may provide a coating (2) wherein the single polymer layer (6) comprising the synergist comprises discrete layers of the two or more layers, (6A) and (6B), from which it is formed. In other embodiments, there may be no discontinuity in the coating (2) between the individual layers, (6A) and (6B), from which the single layer (6) comprising the synergist is formed.

Where the method comprises providing a laminate, for example a first laminate (2A) or a second laminate (2B), the laminate may be provided with a release or peel sheet on the surface of the laminate to be joined, or otherwise laminated. The release or peel sheet is removed to expose the surface of laminate prior to lamination.

Laminate(s) useful in the method may be prepared by any suitable method known in the art. For example, layers of the laminate(s) may be extruded separately and then joined or otherwise laminated together with one or more other polymer layers of the laminate in the desired sequence. Alternatively, layers of the laminate may be co-extruded simultaneously, for example from a single extruder or die, or layers of the laminate may be extruded in series from two or more (or preferably three) serially arranged extruders.

Polymer layers of the coating may be formed from a plurality of polymer layers by laminating or otherwise joining the plurality polymers layers. The plurality of polymer layers may be provided as individual layers and/or as laminates comprising two or more of the plurality of polymer layers in a form suitable for lamination or joining with other polymer layers of the plurality of polymer layers. For example, for ease of manufacture, individual polymer layers or laminates of two more polymer layers may be provided in the form of a roll that may be unrolled for lamination or joining. The polymer layers or laminates may comprise a peel or release sheet that is removed to expose the surface to be laminated or joined.

In some embodiments, the coating is a form provided as a length L and of width W is wound upon a roll for a subsequent unrolling and coating or lamination to a substrate to be coated by the coating.

In some embodiments, the coating is provided with at least one release sheet, which upon release exposes a surface of the coating for coating or lamination or otherwise adhesion or connection or joining to a substrate.

A fire retardant laminate with high optical transparency is disclosed which, in one form, incorporates a first halogenated film or top layer, at least a second bonding layer and a synergist which is incorporated into the bonding layer.

In one embodiment the halogenated layer or top layer is chosen for its environmental durability and light transmission properties. In a preferred embodiment, the top layer may comprise, or may be selected from one or more of: fluoropolymer or chlorofluoropolymer films, more preferentially such as those, but not limited to, ethylene tetrafluoroethylene, ethylene chlorotrifluoroethylene, polyvinylidinefluoride, polyvinylfluoride, fluorinated ethylene propylene, perfluoralkoxy, polychlorotrifluoroethylene, polyvinyl chloride, polyvinylidine chloride, tetrafluoroethylene-hexafluoropropylene-vinylidene fluoride terpolymer, fluoroethylene vinyl ether, copolymers and terpolymers of vinylidene fluoride with any of hexafluoropropylene, tetrafluoroethylene, or chlorotrifluoroethylene, or any combination of any two or more thereof.

In another embodiment, a non-halogenated polymer film may be selected for the top layer, and halogenated additives may be added to such a non-halogenated polymer film. Various non-halogenated polymer films may comprise, or may be selected from one or more of: polycarbonate, polymethylmethacrcylate, polyethylene terephthalate, polyethylene naphthalate, polyethylene terephthalate glycol-modified, polypropylene, polyethylene, cyclic olefin copolymer

In one embodiment a second layer may be selected for its adhesion to the first layer and the underlying substrate, its elastomeric properties which can impart a level of mechanical protection to the underlying substrate, and also its light transmission properties. Such a second layer may comprise, or be selected from one or more of: thermoplastic, thermosetting, radiation curable and pressure sensitive materials.

Thermosetting materials may comprise, or may be selected from, but not limited to, one or more of: epoxies, phenolics, polyurethanes, silicones, methacrylates, polyimides, polycyanurates, vinylester and polyester resins.

Thermoplastic materials may comprise, or may be selected from, but not limited to, one or more of: ethylene vinyl acetate, poly vinyl butyrate, silicone-polyurethane copolymers, polyolefins, thermoplastic polyurethanes, copolyester and copolyamides.

Radiation curable materials may comprise, or may be selected from, but not limited to, one or more of: acrylates, cationic curable materials.

Pressure sensitive materials may comprises, or may be selected from, but not limited to, one or more of: silicones, acrylics, natural rubbers, ethylene vinyl acetates, styrene block copolymers.

In a preferred embodiment, a second layer, or the layer used for its adhesion to another layer and the underlying substrate, is a thermoplastic material.

In one embodiment an inorganic synergist can be added to a second or subsequent layer(s) of the laminate, or any one of these layers. In a preferred embodiment, a synergist compound may comprise, or be selected from, but not limited to, any one or more of: antimony trioxide, antimony pentoxide, and others known to those skilled in the art, for example, sodium antimonate, are incorporated. In a preferred embodiment a pentavalent oxide of antimony, such as antimony pentoxide or sodium antimonate, is used. In a preferred embodiment antimony pentoxide is used.

One method of maintaining the optical transmission of optically transparent materials after adding another material to another is to closely match the refractive indices of the of the matrix and additive. Antimony pentoxide has a refractive index in the region of about 1.7. Sodium antimonate also has a refractive index in the region of about 1.7. Thermoplastic materials useful in the present invention often have refractive indices which differ more than about 0.1 with this value. This difference can cause scattering with an associated undesirable loss in optical transmission. An improvement to the optical transmission can be achieved by using antimony pentoxide or sodium antimonate with very small particle size and ensuring effective dispersion of the particles to prevent particle agglomeration. Antimony pentoxide or sodium antimonate provided as nano-particles (or particles of a nano-size) can be manufactured by those skilled in the art and are commercially available.

Prior art describes combinations of nanometer scale particles of antimony compounds and halogenated materials which optimally are in intimate contact with one another, such that they are homogenously dispersed together in a common matrix. According to the present invention, the combinations of nanometer scale particles of an antimony synergist and a halogenated material can also be effective when the halogenated material is homogenously dispersed through at least one layer of a laminate, and the antimony synergist is homogenously dispersed through at least one other discrete layer of the laminate, for example an adjacent layer.

In one embodiment the halogen material containing layer is about 5 μm to about 10 mm thick, more preferably about 10 μm to about 5 mm thick, more preferably about 15 μm to about 2 mm thick. For example, the halogen material containing layer may be 5 μm to 1 mm thick, 5 μm to 500 μm thick, 10 μm to 500 μm thick, 5 μm to 200 μm thick, 10 μm to 200 μm thick, 15 to 200 μm thick, 10 μm to 100 μm thick, 20 to 100 μm thick, or 25 to 75 μm thick.

In one embodiment the antimony synergist containing layer is about 5 μm to about 10 mm thick, more preferably about 10 μm to about 5 mm thick, more preferably about 15 μm to about 2 mm thick. For example, the synergist containing layer may be 5 μm to 1 mm thick, 5 μm to 750 μm thick, 10 μm to 750 μm thick, 5 μm to 500 μm thick, 10 μm to 500 μm thick, 15 to 500 μm thick, 5 μm to 250 μm thick, 10 μm to 250 μm thick, 15 μm to 250 μm thick, 20 to 250 μm thick, 5 μm to 150 μm thick, 10 μm to 150 μm thick, 15 μm to 150 μm thick, 20 to 150 μm thick, or 50 to 150 μm thick.

One or each layer of the coating or laminate or laminate arrangement may optionally additionally comprise, or be selected from, but not limited to, one or more of: other additives such as light stabilisers, UV absorbers, adhesion promoters, antistatic agents, slip agents, rheological modifiers to control other properties of each layer or the arrangement of layers or laminate so formed.

One or each layer of the coating or laminate or laminate arrangement may optionally additionally comprise one or more dispersants, for example to ensure efficient dispersion of the at least one synergist. Examples of dispersants include ethylene stearamide, ethylene oleamide, montan wax, behenamide, and stearyl erucamide.

In one mode of the invention, the presence of a flame source may provide for an effective local melt blending of the halogenated material and the antimony synergist to facilitate flame retardant properties in the laminate.

In a further aspect on the invention, the addition rate of the synergist to the laminate or a layer of the laminate, may be varied to affect the resultant flame retardant properties necessary as a function of the total fuel load associated to the combination of the layers.

In one form, the percentage loading of the synergist, for example an antimony synergist, may be sufficient to quench, counteract, or retard the fire characteristics or combustion of the bond layer in which the synergist is present. Without wishing to be bound by theory, it is believed that the antimony synergist acts as a catalyst/synergist to release from the halogenated material in the presence of a flame source halogen species in sufficient amounts to achieve the desired level of flame retardance.

The synergist, for example the antimony synergist, may be located preferably within the layer, for example a bond layer, adjacent to the halogenated layer, in sufficient quantities to provide the desired level of flame retardance. In one particular form, the synergist is located in a polymer layer disposed immediately beneath the polymer layer comprising the halogenated material.

In one form, for example, the halogenated layer may be 25-50 um in thickness, and the bond layer comprising the synergist may be 25-500 um. By incorporating the synergist, for example an antimony synergist, in an amount sufficient to provide the desired level of flame retardance into a thicker bond layer, the percentage loading of the synergist is lower than if the synergist is dispersed into a thinner halogenated layer.

Incorporating a high loading of the synergist into a thin halogenated layer may reduce the light transmission properties of the halogenated layer. By dispersing the synergist in a thicker bond layer, it is possible to maintain a useful level of light transmission capability.

The addition of either the synergist or antimony, when in a particulate form can be achieved by someone skilled in the art of compounding, by either or both of the use of: a high speed mixer, which uses high speed and shear to disperse the particles evenly into one of the polymer matrices; or by grinding one of the polymer matrices and mixing it with the synergist or antimony to produce a homogenous blend of the powdered materials.

A polymer layer comprising a halogenated material may have low combustibility, but a second or bonding layer is typically highly combustible. The present invention is capable of imparting flame retardance capability to coatings comprising such highly combustible layers.

### EXAMPLES

### Example 1

100 g of Nyacol Burnex ADP 494 (antimony pentoxide with an average particle size of 40 nm) and 10 g of a dispersant was added to a Henschel high speed mixer. The resultant material was added to a twin screw extruder with 1 kg of a thermoplastic polyurethane polymer (Bayer Texin Sun 3006) having a Shore hardness of 86A as determined by the manufacturer and optical transmission of 0.92 as determined by ASTM D1003. The resultant material has an optical transmission of 0.61 as determined by ASTM D1003.

### Example 2

50 g of Nyacol Burnex ADP 494 and 1 kg of a thermoplastic polyurethane polymer (Bayer Texin Sun 3006) having a Shore hardness of 86A and optical transmission of 0.92 were combined as described in Example 1. The resultant material has an optical transmission of 0.82 as determined by ASTM D1003.

### Example 3

Flame retardance of the material from Example 1 was evaluated according to UL 790-2008. A 200 μm thick film was extruded and laminated to 50 μm ETFE film. The resultant laminate has an optical transmission of 0.61 as determined by ASTM D1003. The laminate was fastened to calcium silicate board covered with a non-combustible roof deck underlay mounted at 22° above horizontal. A flame calibrated to UL 790 Class A was impinged upon the sample for 10 minutes. Spread of flame was measured as 1.6 m.

### Example 4

Flame retardance of the material from Example 2 was evaluated according to UL790. A 200 μm thick film was extruded and laminated to 50 μm ETFE film. The resultant laminate has an optical transmission of 0.82 as determined by ASTM D1003. The laminate was fastened to calcium silicate board covered with a non-combustible roof deck underlay mounted at 22° above horizontal. A flame calibrated to UL 790 Class A was impinged upon the sample for 10 minutes. Spread of flame was measured as 1.7 m.

### Example 5

Flame retardance of the thermoplastic polyurethane (Bayer Texin Sun 3006) from Examples 1 and 2, without the incorporation of the antimony synergist was evaluated according to UL790. A 200 μm thick film was extruded and laminated to 50 μm ETFE film. The laminate was fastened to calcium silicate board covered with a non-combustible roof deck underlay mounted at 22° above horizontal. A flame calibrated to UL 790 Class A was impinged upon the sample for 10 minutes. Spread of flame reached 4 m in two minutes.

### Example 6

Three square samples (samples 1-3 as described below) measuring 100 mm×100 mm were prepared for cone calorimeter testing and tested according to ASTM E1354-15a using a heat flux of 35 kW/m².

Each sample comprised a multilayer coating on a solar cell substrate. The total thickness of the multilayer coating in each sample was 250 um. Samples 1 and 2 were identical.

The structures of the samples were as follows. The layers of the multilayer coating of each sample are listed in order from top (the top layer of the coating) to bottom (the layer adhered or attached to the substrate). The thickness of each layer is indicated in parenthesis.

Samples 1 and 2. Layer 1 (the top layer): ETFE (50 um); Layer 2: DNP Z68 solar encapsulant (a thermoplastic polyolefin solar encapsulant) (20 um); Layer 3: DNP Z68 solar encapsulant+5% by weight sodium antimonate (80 um); Layer 4: DNP Z68 solar encapsulant+5% by weight sodium antimonate (80 um); Layer 5 (the bottom layer): DNP Z68 solar encapsulant (20 um); Substrate: solar cell.
Sample 3. Layer 1 (the top layer): ETFE (50 um); Layer 2 (the bottom layer): DNP Z68 solar encapsulant (200 um); Substrate: solar cell.

Samples 1 and 2 were prepared as follows. A 20 um layer of solar encapsulant containing no antimony and an 80 um layer of solar encapsulant containing 5% sodium antimonate by weight were coextruded in a 300 mm wide coat hanger die and cast onto polished chrome rollers.

Two layers of this coextruded encapsulant were assembled above a solar cell and covered by an ETFE sheet. The assembly was laminated in a Spire SpiLam vacuum laminator at 155° C. for 18 minutes.

The assemblies were then trimmed to 100 mm×100 mm square for cone calorimeter testing.

Results of the tests are summarised in Table 1 below.

TABLE 1
Peak heat release rate and total heat released in Cone
Calirometer testing of samples 1-3.

| Sample | Heat release rate peak (kW/m²) | Total heat released (MJ/m²) |
|---|---|---|
| 1 | 338.70 | 13.02 |
| 2 | 340.18 | 12.46 |
| 3 | 412.44 | 18.95 |

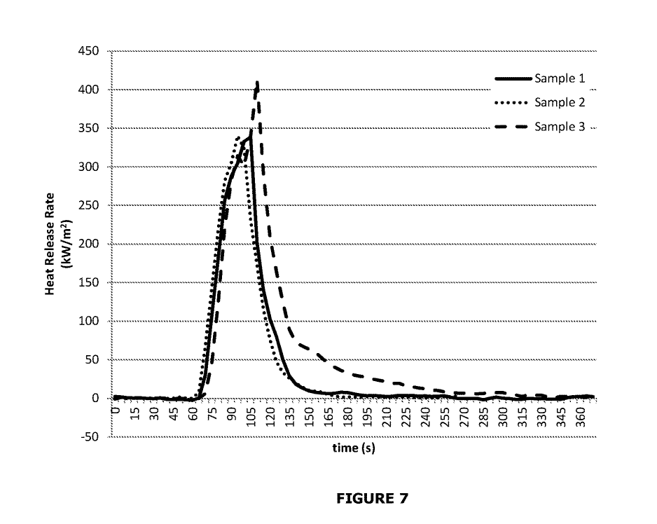

The results show that the peak heat release rates and total heat released by samples 1 and 2 are significantly lower than the peak heat release rate and total heat released by sample 3, which did not include a layer comprising a synergist. A plot of the heat release rate for each sample (in kW/m²) over time (in seconds) is shown in FIG. 7. The time of ignition of each sample was substantially the same. The total heat released corresponds to the area under the curve for each sample.

The following paragraphs relate to aspects and embodiments of the invention:

1. A multilayer coating for a substrate having flame retardant capability, the coating comprising two or more layers,

wherein at least one layer of the two or more layers is a carrier layer comprising a halogenated material and at least one other layer of the two or more layers comprises at least one synergist.

2. The coating of paragraph 1, wherein the carrier layer comprising the at least one halogenated material and the carrier layer comprising the at least one synergist are effective to provide the at least one halogenated material and the at least one synergist on thermal degradation, burning or pyrolysis.
3. A multilayer coating for a substrate having flame retardant capability, the coating comprising two or more polymer layers,
wherein at least one polymer layer of the two or more polymer layers comprises at least one halogenated material and at least one other polymer layer of the two or more polymer layers comprises at least one synergist.
4. A multilayer coating for a substrate having flame retardant capability, the coating comprising two or more polymer layers,

wherein at least one polymer layer of the two or more polymer layers comprises at least one halogenated material and at least one other polymer layer of the two or more polymer layers comprises at least one synergist,

wherein the polymer layer comprising the at least one halogenated material is a top layer and the polymer layer comprising the at least one synergist is a layer disposed beneath the top layer, and

wherein the polymer layer comprising the at least one halogenated material has a higher melting point that the polymer layer comprising the at least one synergist.

5. A multilayer coating for a substrate having flame retardant and optical transmission capability, the coating comprising two or more polymer layers,

wherein at least one polymer layer of the two or more polymer layers comprises at least one halogenated material and at least one other polymer layer of the two or more polymer layers comprises at least one synergist, and

wherein the coating transmits at least about 50% of incident radiation in the wavelength range of about 400-900 nm, preferably 400-700 nm.

6. A multilayer protective coating for a photovoltaic module or cell having flame retardant and optical transmission capability, the coating comprising two or more polymer layers,

wherein at least one polymer layer of the two or more polymer layers comprises at least one halogenated material and at least one other polymer layer of the two or more polymer layers comprises at least one synergist,

wherein the protective coating transmits at least about 50% of incident radiation in the wavelength range of about 400-900 nm, preferably 400-700 nm, and

wherein the coating is adhered to a photo-receptive side of the photovoltaic module or cell.

7. The coating of any one of paragraphs 1-6, wherein the halogenated material is organic.
8. The coating of any one of paragraphs 1-7, wherein the halogenated material is a halogenated polymer.
9. The coating of paragraph 8, wherein the halogenated polymer comprises a fluoropolymer or a chlorofluoropolymer, or a combination thereof.
10. The coating of paragraph 9, wherein the fluoropolymer or chlorofluoropolymer comprises ethylene tetrafluoroethylene, ethylene chlorotrifluoroethylene, polyvinylidinefluoride, polyvinylfluoride, fluorinated ethylene propylene, perfluoralkoxy, polychlorotrifluoroethylene, polyvinyl chloride, polyvinylidine chloride, tetrafluoroethylene-hexafluoropropylene-vinylidene fluoride terpolymer, fluoroethylene vinyl ether, copolymers and terpolymers of vinylidene fluoride with any of hexafluoropropylene, tetrafluoroethylene, chlorotrifluoroethylene, or any combination of any two or more thereof.
11. The coating of any one of paragraphs 1-7, wherein the halogenated material is a flame retardant brominated or chlorinated organic compound or polymer.
12. The coating of paragraph 11, wherein the flame retardant brominated organic compound or polymer is hexabromocyclodecane, decabromodiphenyl ethane, poly(dibromostyrene), tetrabromophthalic anhydride, tetrabromophthalate diol, tetrabromophthalate ester, tetrabromobisphenol A, 2,4,6 tribromophenol, or tribromophenyl allyl ether, or any combination of two or more thereof.
13. The coating of any one of paragraphs 1-12, wherein the synergist is inorganic.
14. The coating of any one of paragraphs 1-13, wherein the synergist comprises an inorganic metal compound.
15. The coating of paragraph 14, wherein the metal compound comprises a zinc, tin, molybdenum, zirconium, and antimony compound, or any combination of any two or more thereof.
16. The coating of any one of paragraphs 1-15, wherein the synergist comprises an antimony compound.
17. The coating of paragraph 16, wherein the antimony compound is an oxide of antimony.
18. The coating of paragraph 16 or 17, wherein the antimony compound comprises antimony pentoxide or antimony trioxide, or a combination thereof.
19. The coating of any one of paragraphs 1-18, wherein the synergist is in the form of particles.
20. The coating of paragraph 19, wherein the particles are substantially uniformly dispersed throughout the polymer layer.
21. The coating of paragraph 19 or 20, wherein the size of the particles is such that the polymer layer transmits at least about 50, 60, 70, 80, or 85% of the total incident radiation in the wavelength range of about 400-900 nm, preferably 400-700 nm.
22. The coating of any one of paragraphs 19-21, wherein the particles have an average particle size from about 1 to about 5000 nm, 1 to 2000 nm, from about 1 to about 1000 nm, 5 to 1000 nm, 1 to 500 nm, 5 to 500 nm, 1 to 300 nm, 5 to 300 nm, 10 to 300 nm, 10 to 250 nm, 15 to 150 nm, 20 to 100 nm, 25 to 75 nm, or 30-40 nm.
23. The coating of any one of paragraphs 1 to 22, wherein the synergist is present in an amount effective to retard combustion of the coating on thermal degradation, burning, or pyrolysis.
24. The coating of paragraph 23, wherein the amount is sufficient to retard combustion of the total fuel load of the coating.
25. The coating of any one of paragraphs 1-24, wherein the synergist is present in an amount from about 0.1% to about 30% by weight of the polymer layer.
26. The coating of any one of paragraphs 1-25, wherein the synergist is present in an amount from about 0.5% to about 25% by weight of the polymer layer.
27. The coating of any one of paragraphs 1-26, wherein the synergist is present in an amount from about 1% to about 10% by weight of the polymer layer.
28. The coating of any one of paragraphs 1-27, wherein the synergist is present in an amount from about 2% to about 8% by weight of the polymer layer.
29. The coating of any one of paragraphs 1-28, wherein the polymer layer comprising the halogenated material is devoid of a synergist.
30. The coating of any one of paragraphs 1-29, wherein the polymer layer comprising the halogenated material is of a thickness substantially less than the polymer layer comprising the synergist.
31. The coating of any one of paragraphs 1-30, wherein the polymer layer comprising the halogenated material is devoid of a synergist, and is of a layer thickness of about: 5 μm to 1 mm thick, 5 μm to 500 μm thick, 10 μm to 500 μm thick, 5 μm to 200 μm thick, 10 μm to 200 μm thick, 15 to 200 μm thick, 10 μm to 100 μm thick, 20 to 100 μm thick, or 25 to 75 μm thick.
32. The coating of any one of paragraphs 1-31, wherein the polymer layer comprising the synergist is devoid of a flame retardant, and is of a layer thickness of about: 5 μm to 1 mm thick, 5 μm to 750 μm thick, 10 μm to 750 μm thick, 5 μm to 500 μm thick, 10 μm to 500 μm thick, 15 to 500 μm thick, 5 μm to 250 μm thick, 10 μm to 250 μm thick, 15 μm to 250 μm thick, 20 to 250 μm thick, 5 μm to 150 μm thick, 10 μm to 150 μm thick, 15 μm to 150 μm thick, 20 to 150 μm thick, or 50 to 150 μm thick.
33. The coating of any one of paragraphs 1-32, wherein one of the polymer layers comprises a halogenated polymer as a halogenated material, is devoid of an antimony compound or oxide of antimony as a synergist, and is of a layer thickness substantially less than the layer thickness of another polymer layer comprising an antimony compound or oxide of antimony as a synergist.
34. The coating of any one of paragraphs 1-33, wherein the coating has a thickness of less than about 2 mm, 1 mm, 750 μm, 500 μm, 400 μm, 300 μm, or 250 μm.
35. The coating of any one of paragraphs 1-34, wherein at least one polymer layer of the two or more polymer layers is a thermoplastic, thermosetting, radiation cured or pressure sensitive adhesive material.
36. The coating of any one of paragraphs 1-35, wherein the polymer layer which is to be located adjacent to or upon a substrate to be coated is provided as a thermoplastic, thermosetting, radiation cured or pressure sensitive adhesive material.
37. The coating of any one of paragraphs 1-36, wherein the coating comprises more than two polymer layers.
38. The coating of paragraph 37, wherein the coating comprises two or more polymer layers comprising a synergist and/or two or more polymer layers comprising a halogenated material.
39. The coating of any one of paragraphs 1-38, wherein the coating is formed by a first polymer layer and a second polymer layer, wherein:

the first polymer layer comprises the at least one halogenated material and the second polymer layer comprises the at least one synergist, or

the first polymer layer comprises the synergist and the second polymer layer comprises the at least one halogenated material.

40. The coating of paragraph 39, wherein the first polymer layer comprises the at least one halogenated material and the second polymer layer comprises the at least one synergist.
41. The coating of any one of paragraphs 39 or 40, wherein the first polymer layer is a top layer and the second polymer layer is a layer disposed beneath the top layer.
42. The coating of any one of paragraphs 39-41, wherein the second polymer layer is provided to attach the first polymer layer to a substrate to receive the coating.
43. The coating of any one of paragraphs 39-42, wherein one or more additional layers are provided intermediate of the top layer and the bottom layer.
44. The coating of any one of paragraphs 39-43, wherein the first layer is a top layer that transmits at least about 50, 60, 70, 80, or 85% of the total incident radiation in the wavelength range of about 400-900 nm, preferably 400-700 nm, and the second layer is a layer disposed beneath the first layer.
45. The coating of paragraph 44, wherein the second layer transmits at least about 50, 60, 70, 80, or 85% of the total incident radiation in the wavelength range of about 400-900 nm, preferably 400-700 nm.
46. The coating of any one of paragraphs 1-45, wherein each of the one or more polymer layers transmits at least about 50% of the total incident radiation in the wavelength range of about 400-900 nm, preferably 400-700 nm.
47. The coating of any one of paragraphs 1-46, wherein each of the one or more polymer layers transmits at least about 70% of the total incident radiation in the wavelength range of about 400-900 nm, preferably 400-700 nm.
48. The coating of any one of paragraphs 1-47, wherein each of the one or more polymer layers transmits at least about 85% of the total incident radiation in the wavelength range of about 400-900 nm, preferably 400-700 nm.
49. The coating of any one of paragraphs 1-48, wherein the coating transmits at least about 50, 60, 70, 80, or 85% of the total incident radiation in the wavelength range of about 400-900 nm, preferably 400-700 nm.
50. The coating of any one of paragraphs 1-49, wherein the polymer layer comprising the at least one halogenated material has a higher melting point than the polymer layer comprising the at least one synergist.
51. The coating of paragraph 50, wherein the melting point of the polymer layer comprising the at least one halogenated material is at least about 20, 25, 50, 75, 100, 125, 150, 175, 200, 225, or 250° C. more than that melting point of the polymer layer comprising the at least one synergist.
52. The coating of paragraph 50 or 51, wherein the polymer layer comprising the at least one halogenated material has a melting point from about 100 to 600° C., 150 to 550° C., or 200 to 500° C.
53. The coating of any one of paragraphs 51-52, wherein the melting point of the polymer layer comprising the synergist is from about 0 to 400° C., 50 to 350° C., or 100 to 300° C.
54. The coating of any one of paragraphs 1-53, wherein a bottom layer of the coating provided to attach the at least one other polymer layer of the coating to the substrate has a Shore D hardness of less than about 70D, and an elongation at break of at least about 100%.
55. The coating of any one of paragraphs 1-54, wherein the a bottom layer of the coating provided to attach the at least one other polymer layer of the coating to the substrate has a Shore D hardness of less than about 40D, and an elongation at break of at least about 200%.
56. The coating of any one of paragraphs 1-55, wherein the coating has a peel strength between the substrate and a bottom layer of the coating provided to attach the at least one other polymer layer of the coating to the substrate of at least about 300 N/m.
57. The coating of any one of paragraphs 1-56, wherein the coating has a peel strength between the substrate and a bottom layer of the coating provided to attach the at least one other polymer layer of the coating to the substrate of at least about 500 N/m.
58. The coating of any one of paragraphs 1-57, wherein the coating has a cut resistance determined according to UL1703.24 (2012 revised version) of at least about 2 lb.
59. The coating of any one of paragraphs 1-5 and 7-58, wherein a substrate to receive the coating is one or more of: architectural panels, building or construction materials, structural building membranes, inflatable structures, signage, window overlays, electronic displays or electronic surfaces, photovoltaic modules or cells, rigid composite structures, and medical devices, or aircraft or automobile interiors.
60. The coating of any one of paragraphs 1-5 and 7-59, wherein a substrate to receive the coating is, or comprises, a photovoltaic module or cell.
61. The coating of any one of paragraphs 1-5 and 7-60, wherein the coating is adhered to a photo-receptive side or surface of a photovoltaic module or cell.
62. The coating of any one of paragraphs 1-61, wherein the coating is laminated to or upon the substrate.
63. The coating of any one of paragraphs 1-62, wherein the coating is a film, sheet, coating or laminate arrangement provided for application to a substrate.
64. The coating of any one of paragraphs 1-63, wherein the coating has a class A, B, or C flame retardance rating as determined according to UL 790-2008.
65. The coating of any one of paragraphs 16-64, wherein the antimony compound comprises antimony in the oxidation state of +5 or +3.
66. The coating of any one of paragraphs 16-65, wherein the antimony compound comprises a pentavalent or trivalent oxide of antimony.
67. The coating of any one of paragraphs 17-66, wherein the oxide of antimony comprises antimony trioxide, antimony pentoxide or sodium antimonate, or a combination of any two or more thereof.
68. The coating of paragraph 66 or 67, wherein the pentavalent oxide of antimony comprises antimony pentoxide or an antimonate salt.
69. The coating of paragraph 68, wherein the antimonate salt is an alkali metal salt, for example sodium antimonate.
70. The coating of any one of paragraphs 39-69, wherein one or more additional polymer layers are provided intermediate to the first polymer layer and second polymer layer to attach the first polymer layer to the second polymer layer.
71. The coating of any one of paragraphs 39-70, wherein one or more additional polymer layers are provided intermediate to the second polymer layer and a substrate to receive the coating to attach the second polymer layer to the substrate to receive the coating.
72. The coating of any one of paragraphs 1-71, wherein one or more additional polymer layers that provide a physical and/or chemical barrier to reaction between the synergist and the substrate are provided intermediate to the polymer layer comprising the synergist and a substrate to receive the coating.
73. The coating of any one of paragraphs 1-72, wherein one or more additional polymer layers that inhibit or prevent degradation of the substrate by the synergist are provided intermediate to the polymer layer comprising the synergist and a substrate to receive the coating.
74. The coating of any one of paragraphs 1-73, wherein one or more additional polymer layers that inhibit or prevent corrosion of the substrate by the synergist are provided intermediate to the polymer layer comprising the synergist and a substrate to receive the coating.
75. The coating of any one of paragraphs 1-74, wherein the polymer layer comprising the synergist is formed from two or more polymer layers of the substantially the same composition comprising the synergist.
76. The coating of any one of paragraphs 1-74, wherein the coating comprises:

a first polymer layer comprising at least one halogenated material as a top layer,

a second polymer layer comprising at least one synergist disposed beneath the first layer,

optionally, one or more additional polymer layers provided intermediate to the first polymer layer and the second polymer layer to attach the first polymer layer to the second polymer layer, and

optionally, one or more additional polymer layers provided intermediate to the second polymer layer and a substrate to receive the coating to attach the second polymer layer to the substrate,

wherein the one or more additional polymer layers provided intermediate to the second polymer layer and the substrate to receive the coating inhibit or prevent degradation, for example corrosion, of the substrate by the synergist.

77. A substrate coated with a coating of any one of paragraphs 1-76.
78. A photovoltaic module or cell coated with a coating of any one of paragraphs 1-76.
79. The photovoltaic module or cell of paragraph 78, wherein the coating is adhered to a photo-receptive side or surface of the photovoltaic module or cell.
80. A method of coating a substrate with a coating, comprising laminating the coating as defined in any one of the preceding paragraphs.
81. The method of paragraph 80, wherein the coating encapsulates or is encapsulating of the substrate.
82. A method of manufacturing a coating of any one of paragraphs 1 to 76, the method comprising the steps of:

providing at least one polymer with at least one synergist, where the at least one synergist is substantially uniformly dispersed within the at least one polymer,

providing at least one other polymer comprising at least one halogenated material, and

joining, laying upon each other or otherwise laminating together the, or each of, the at least one polymer and the at least one other polymer as separate layers of a protecting coating or the protective coating as herein defined.

83. The method of paragraph 82, wherein the at least one polymer is provided in the form of a laminate comprising a layer of the at least one polymer and one or more additional polymer layers.
84. The method of paragraph 82 or 83, wherein the at least one other polymer is provided in the form of a laminate comprising a layer of the at least one other polymer and one or more additional polymer layers.
85. The method of any one of paragraph 82-84, wherein the method comprises:

providing a laminate comprising a layer of the at least one polymer and one or more additional polymer layers,

providing a laminate comprising a layer of the at least one other polymer and one or more additional polymer layers, and

joining, laying upon each other or otherwise laminating together the laminate comprising the at least one polymer and the laminate comprising the at least one other polymer.

86. The method of any one of paragraph 83-85, wherein the laminate comprising the at least one other polymer comprises a polymer layer comprising at least one synergist as a bottom layer.
87. The method of paragraph 85 or 86, wherein the layer of the at least one polymer is a top layer, and the method comprises laminating the top layer of the laminate comprising the at least one polymer and the synergist containing bottom layer of the laminate comprising the at least one other polymer to provide a single polymer layer comprising at least one synergist.
88. The method of any one of paragraph 82-87, wherein the method comprises the steps of:

providing a first laminate comprising
a layer of the at least one polymer with at least one synergist as a top layer, and
optionally one or more additional polymer layers provided intermediate to the top layer and a substrate to receive the coating to attach the top layer to the substrate,
wherein the one or more additional polymer layers intermediate to the top layer and the substrate to receive the coating inhibit or prevent degradation of the substrate by the synergist,

providing a second laminate comprising
a layer of the at least one other polymer comprising at least one halogenated material as a top layer,
a polymer layer comprising at least one synergist as a bottom layer, and
optionally one or more additional polymer layers provided intermediate to the top layer and a bottom layer to attach the top layer to the bottom layer, and

joining, laying upon each other or otherwise laminating together the top layer of the first laminate and the bottom layer of the second laminate.

89. The method of paragraph 88, wherein the composition of the top layer of the first laminate and the composition of the bottom layer of the second laminate is the substantially same.
90. The method of paragraph 88 or 89, wherein laminating the top layer of the first laminate and the bottom layer of the second laminate provides a single polymer layer comprising the at least one synergist.
91. The coating of any one of paragraphs 1 to 76, wherein a form provided as a length L and of width W is wound upon a roll for a subsequent unrolling and coating or lamination to a substrate to be coated by the coating.
92. The coating, substrate, module or cell, or method of any one of paragraphs 1 to 76, wherein the coating is provided with at least one release sheet, which upon release exposes a surface of the coating for coating or lamination or otherwise adhesion or connection or joining to a substrate.
93. The coating, substrate, module or cell, or method any one of paragraphs 1 to 76, wherein at least one layer of the coating comprises an adhesion promoter, for example a silane, maleic anhydride, or glycidyl methacrylate based adhesion promoter.
94. The coating, substrate, module or cell, or method of paragraph 93, wherein the layer comprising the adhesion promoter is layer an adhesion or adhering layer provided to attach a layer disposed above the adhesion or adhering layer to a layer disposed below the adhesion or adhering layer or to attach a layer disposed above the adhesion or adhering layer to a substrate to receive the coating.
95. The coating, substrate, module or cell, or method of any one paragraphs 1-76, wherein the coating has a peel strength between the substrate a bottom layer provided to attach the at least one other polymer layer of 50, 60, 70, 80, 90, 100, 125, 150, 200, 250, 300, 350, 400, 450, 500, 600, 700, 800, 900, 1000, 1500, 2000 N/m, or more, and useful ranges may be selected from any two or more of the preceding values, for example from 50 to 2000, 60 to 2000, 100 to 2000, 300 to 2000, 500 to 2000, 700 to 2000, 50 to 1500, 60 to 1500, 100 to 1500, 300 to 1500, 500 to 1500, or 700 to 1500, 50 to 1000, 60 to 1000, 100 to 1000, 300 to 1000, 500 to 1000, or 700 to 1000 N/m.
96. The coating, substrate, module or cell, or method of any one of paragraphs 87 to 95, wherein the single polymer layer comprising the at least one synergist comprises discrete layers of the top layer of the first laminate or laminate comprising at least one polymer and the bottom layer of the second laminate or laminate comprising at least one other polymer.
97. The coating, substrate, module or cell, or method of any one of paragraphs 1 to 96, wherein the polymer layer comprising the at least one synergist, such as a second polymer layer, comprises two or more discrete polymer layers comprising the at least one synergist.
98. The coating, substrate, module or cell, or method of paragraph 97, wherein the two or more discrete polymer layers have the same or substantially the same composition, and/or have different compositions and/or both where the discrete polymer layers used may provide for a combination of the same or substantially the same and different compositions.
99. The coating, substrate, module or cell, or method of any one of paragraphs 1 to 98, wherein the coating has a heat release peak in kW/m² is at least 5, 10, 15, 20, 25, 30, or 35% less than the same coating without the at least one synergist.
100. The coating, substrate, module or cell, or method of any one of paragraphs 1 to 99, wherein the coating has a total heat released in MJ/m² is at least 10, 15, 20, 25, 30, 35, 40, 45, or 50% less than the same coating without the at least one synergist.

The foregoing description of the invention includes preferred forms thereof. Modifications may be made thereto without departing from the scope of the invention as defined by the accompanying claims.

1. A multilayer coating for a substrate having flame retardant capability, the coating comprising two or more carrier or polymer layers,
wherein at least one carrier or polymer layer of the two or more carrier or polymer layers is a carrier or polymer layer comprising a halogenated material and at least one other carrier or polymer layer of the two or more carrier or polymer layers comprises at least one synergist.

2. A multilayer coating for a substrate having flame retardant capability, the coating comprising two or more polymer layers,
wherein at least one polymer layer of the two or more polymer layers comprises at least one halogenated material and at least one other polymer layer of the two or more polymer layers comprises at least one synergist,
wherein the polymer layer comprising the at least one halogenated material is a top layer and the polymer layer comprising the at least one synergist is a layer disposed beneath the top layer, and
wherein the polymer layer comprising the at least one halogenated material has a higher melting point that the polymer layer comprising the at least one synergist.

3. A multilayer coating for a substrate having flame retardant and optical transmission capability, the coating comprising two or more polymer layers,
wherein at least one polymer layer of the two or more polymer layers comprises at least one halogenated material and at least one other polymer layer of the two or more polymer layers comprises at least one synergist, and
wherein the coating transmits at least about 50% of incident radiation in the wavelength range of about 400-900 nm, preferably 400-700 nm.

4. A multilayer protective coating for a photovoltaic module or cell having flame retardant and optical transmission capability, the coating comprising two or more polymer layers,
wherein at least one polymer layer of the two or more polymer layers comprises at least one halogenated material and at least one other polymer layer of the two or more polymer layers comprises at least one synergist,
wherein the protective coating transmits at least about 50% of incident radiation in the wavelength range of about 400-900 nm, preferably 400-700 nm, and
wherein the coating is adhered to a photo-receptive side of the photovoltaic module or cell.

5. The coating as claimed in any one of claims 1-4, wherein the halogenated material is a halogenated polymer.

6. The coating as claimed in claim 5, wherein the halogenated polymer comprises a fluoropolymer or a chlorofluoropolymer, or a combination thereof.

7. The coating as claimed in any one of claims 1-6, wherein the synergist is inorganic.

8. The coating as claimed in any one of claims 1-7, wherein the synergist comprises an antimony compound.

9. The coating as claimed in claim 8, wherein the antimony compound is an oxide of antimony.

10. The coating as claimed in any one of claims 1-9, wherein the synergist is in the form of particles, wherein the particles have an average particle size from about 1 to about 5000 nm, 1 to 2000 nm, from about 1 to about 1000 nm, 5 to 1000 nm, 1 to 500 nm, 5 to 500 nm, 1 to 300 nm, 5 to 300 nm, 10 to 300 nm, 10 to 250 nm, 15 to 150 nm, 20 to 100 nm, 25 to 75 nm, or 30-40 nm.

11. The coating as claimed in claim 10, wherein the size of the particles is such that the polymer layer transmits at least about 50, 60, 70, 80, or 85% of the total incident radiation in the wavelength range of about 400-900 nm, preferably 400-700 nm.

12. The coating as claimed in any one of claims 1-11, wherein the synergist is present in an amount from about 0.1% to about 30%, from about 0.5% to about 25%, from about 1% to about 10%, or from about 2% to about 8% by weight of the polymer layer.

13. The coating as claimed in any one of claims 1-12, wherein the polymer layer comprising the halogenated material is devoid of a synergist.

14. The coating as claimed in any one of claims 1-13, wherein one of the polymer layers comprises a halogenated polymer as a halogenated material, is devoid of an antimony compound or oxide of antimony as a synergist, and is of a layer thickness substantially less than the layer thickness of another polymer layer comprising an antimony compound or oxide of antimony as a synergist.

15. The coating as claimed in any one of claims 1-14, wherein at least one polymer layer of the two or more polymer layers is a thermoplastic, thermosetting, radiation cured or pressure sensitive adhesive material; and/or wherein the polymer layer which is to be located adjacent to or upon a substrate to be coated is provided as a thermoplastic, thermosetting, radiation cured or pressure sensitive adhesive material.

16. The coating as claimed in any one of claims 1-15, wherein the coating comprises more than two polymer layers.

17. The coating of claim 16, wherein the coating comprises two or more polymer layers comprising a synergist and/or two or more polymer layers comprising a halogenated material.

18. The coating as claimed in any one of claims 1-17, wherein the coating is formed by a first polymer layer and a second polymer layer, wherein:
the first polymer layer comprises the at least one halogenated material and the second polymer layer comprises the at least one synergist, or
the first polymer layer comprises the synergist and the second polymer layer comprises the at least one halogenated material.

19. The coating as claimed in claim 18, wherein the first polymer layer comprises the at least one halogenated material and the second polymer layer comprises the at least one synergist.

20. The coating as claimed in any one of claim 18 or 19, wherein the first polymer layer is a top layer and the second polymer layer is a layer disposed beneath the top layer.

21. The coating as claimed in any one of claims 18-20, wherein the second polymer layer is provided to attach the first polymer layer to a substrate to receive the coating; and/or
wherein one or more additional layers are provided intermediate of the top layer and the bottom layer.

22. The coating as claimed in any one of claims 18-21, wherein the first layer is a top layer that transmits at least about 50, 60, 70, 80, or 85% of the total incident radiation in the wavelength range of about 400-900 nm, preferably 400-700 nm, and the second layer is a layer disposed beneath the first layer.

23. The coating as claimed in claim 24, wherein the second layer transmits at least about 50, 60, 70, 80, or 85% of the total incident radiation in the wavelength range of about 400-900 nm, preferably 400-700 nm.

24. The coating as claimed in any one of claims 1-23, wherein each of the one or more polymer layers transmits at least about 50%, 70%, or 85% of the total incident radiation in the wavelength range of about 400-900 nm, preferably 400-700 nm.

25. The coating of any one of claims 1-24, wherein the coating transmits at least about 50, 60, 70, 80, or 85% of the total incident radiation in the wavelength range of about 400-900 nm, preferably 400-700 nm.

26. The coating as claimed in any one of claims 1-25, wherein the polymer layer comprising the at least one halogenated material has a higher melting point than the polymer layer comprising the at least one synergist.

27. The coating of any one of claims 1-26, wherein the coating has a peel strength between the substrate and a bottom layer of the coating provided to attach the at least one other polymer layer of the coating to the substrate of at least about 300 N/m or at least about 500 N/m.

28. The coating of any one of claims 1-27, wherein the coating has a cut resistance determined according to UL1703.24 (2012 revised version) of at least about 2 lb.

29. The coating as claimed in any one of claims 1-3 and 5-28, wherein a substrate to receive the coating is one or more of: architectural panels, building or construction materials, structural building membranes, inflatable structures, signage, window overlays, electronic displays or electronic surfaces, photovoltaic modules or cells, rigid composite structures, and medical devices, or aircraft or automobile interiors.

30. The coating as claimed in any one of claims 1-3 and 5-29, wherein a substrate to receive the coating is, or comprises, a photovoltaic module or cell, and optionally wherein the coating is adhered to a photo receptive side or surface of the photovoltaic module or cell.

31. The coating as claimed in any one of claims 1-30, wherein the coating is laminated to or upon the substrate.

32. The coating as claimed in any one of claims 1-31, wherein the coating is a film, sheet, coating or laminate arrangement provided for application to a substrate.

33. The coating of any one of claims 1-32, wherein the coating has a class A, B, or C flame retardance rating as determined according to UL 790-2008.

34. The coating of any one of claims 9-33, wherein the oxide of antimony comprises antimony trioxide, antimony pentoxide or sodium antimonate, or a combination of any two or more thereof.

35. The coating of any one of claims 18-34, wherein one or more additional polymer layers are provided intermediate to the first polymer layer and second polymer layer to attach the first polymer layer to the second polymer layer; and/or
wherein one or more additional polymer layers are provided intermediate to the second polymer layer and a substrate to receive the coating to attach the second polymer layer to the substrate to receive the coating.

36. The coating of any one of claims 1-35, wherein one or more additional polymer layers that provide a physical and/or chemical barrier to reaction between the synergist and the substrate are provided intermediate to the polymer layer comprising the synergist and a substrate to receive the coating; and/or
wherein one or more additional polymer layers that inhibit or prevent degradation of the substrate by the synergist are provided intermediate to the polymer layer comprising the synergist and a substrate to receive the coating; and/or
wherein one or more additional polymer layers that inhibit or prevent corrosion of the substrate by the synergist are provided intermediate to the polymer layer comprising the synergist and a substrate to receive the coating.

37. The coating of any one of claims 1-36, wherein the polymer layer comprising the synergist is formed from two or more polymer layers of the substantially the same composition comprising the synergist.

38. The coating of any one of claims 1-36, wherein the coating comprises:
a first polymer layer comprising at least one halogenated material as a top layer,
a second polymer layer comprising at least one synergist disposed beneath the first layer,
optionally, one or more additional polymer layers provided intermediate to the first polymer layer and the second polymer layer to attach the first polymer layer to the second polymer layer, and
optionally, one or more additional polymer layers provided intermediate to the second polymer layer and a substrate to receive the coating to attach the second polymer layer to the substrate,
wherein the one or more additional polymer layers provided intermediate to the second polymer layer and the substrate to receive the coating inhibit or prevent degradation, for example corrosion, of the substrate by the synergist.

39. A substrate coated with a coating as claimed in any one of claims 1-38.

40. A photovoltaic module or cell coated with a coating as claimed in any one of claims 1-38, optionally wherein the coating is adhered to a photoreceptive side or surface of the photovoltaic module or cell.

41. A method of coating a substrate with a coating, comprising laminating the coating as defined in any one of claims 1-38.

42. The method as claimed in claim 41, wherein the coating encapsulates or is encapsulating of the substrate.

43. A method of manufacturing a coating as claimed in any one of claims 1 to 38, the method comprising the steps of:
providing at least one polymer with at least one synergist, where the at least one synergist is substantially uniformly dispersed within the at least one polymer,
providing at least one other polymer comprising at least one halogenated material, and
joining, laying upon each other or otherwise laminating together the, or each of, the at least one polymer and the at least one other polymer as separate layers of a protecting coating or the protective coating as herein defined.

44. The method of claim 43, wherein the at least one polymer is provided in the form of a laminate comprising a layer of the at least one polymer and one or more additional polymer layers; or
wherein the at least one other polymer is provided in the form of a laminate comprising a layer of the at least one other polymer and one or more additional polymer layers.

45. The method of claim 43 or 44, wherein the method comprises:
providing a laminate comprising a layer of the at least one polymer and one or more additional polymer layers,
providing a laminate comprising a layer of the at least one other polymer and one or more additional polymer layers, and
joining, laying upon each other or otherwise laminating together the laminate comprising the at least one polymer and the laminate comprising the at least one other polymer.

46. The method of claim 44 or 45, wherein the laminate comprising the at least one other polymer comprises a polymer layer comprising at least one synergist as a bottom layer, the layer of the at least one polymer is a top layer, and the method comprises laminating the top layer of the laminate comprising the at least one polymer and the synergist containing bottom layer of the laminate comprising the at least one other polymer to provide a single polymer layer comprising at least one synergist.

47. The method of any one of claims 43-46, wherein the method comprises the steps of:
providing a first laminate comprising
a layer of the at least one polymer with at least one synergist as a top layer, and
optionally one or more additional polymer layers provided intermediate to the top layer and a substrate to receive the coating to attach the top layer to the substrate,
wherein the one or more additional polymer layers intermediate to the top layer and the substrate to receive the coating inhibit or prevent degradation of the substrate by the synergist,
providing a second laminate comprising
a layer of the at least one other polymer comprising at least one halogenated material as a top layer,
a polymer layer comprising at least one synergist as a bottom layer, and
optionally one or more additional polymer layers provided intermediate to the top layer and a bottom layer to attach the top layer to the bottom layer, and
joining, laying upon each other or otherwise laminating together the top layer of the first laminate and the bottom layer of the second laminate.

48. The method of claim 46 or 47, wherein the single polymer layer comprising the at least one synergist comprises discrete layers of the top layer of the first laminate or laminate comprising at least one polymer and the bottom layer of the second laminate or laminate comprising at least one other polymer.

49. The coating of any one of claims 1 to 38, wherein the polymer layer comprising the at least one synergist comprises two or more discrete polymer layers comprising the at least one synergist.
